(19) United States
(12) Patent Application Publication
(10) Pub. No.: US 2026/0265578 A1
(43) Pub. Date: Sep. 10, 2026

(54) SILICA FINE PARTICLE DISPERSION FOR POLISHING, COMPOSITION FOR POLISHING, AND METHOD FOR PRODUCING SILICA FINE PARTICLE DISPERSION FOR POLISHING

(71) Applicants: Kazuhiro NAKAYAMA, Kitakyushu-shi (JP); Kaoruko YAMASHITA, Kitakyushu-shi (JP); Shinya USUDA, Kitakyushu-shi (JP); Tomoaki MURAKAMI, Kitakyushu-shi (JP); Tatsuya MUKAI, Kitakyushu-shi (JP)

(72) Inventors: Kazuhiro NAKAYAMA, Kitakyushu-shi (JP); Kaoruko YAMASHITA, Kitakyushu-shi (JP); Shinya USUDA, Kitakyushu-shi (JP); Tomoaki MURAKAMI, Kitakyushu-shi (JP); Tatsuya MUKAI, Kitakyushu-shi (JP)

(73) Assignee: JGC CATALYSTS AND CHEMICALS LTD., Kawasaki-shi, Kanagawa (JP)

(21) Appl. No.: 19/481,286

(22) PCT Filed: Apr. 26, 2024
(86) PCT No.: PCT/JP2024/016468

§ 371 Date: Nov. 4, 2025

(51) Int. Cl. C09G 1/02; C01B 33/18; C09K 3/14

(52) U.S. Cl. CPC C09G 1/02; C01B 33/18; C09K 3/1409; C01P 2004/32; C01P 2004/62; C01P 2004/64; C01P 2006/12

(57) ABSTRACT

A dispersion liquid of polishing silica fine particles produced by dispersing, in a solvent, a group of particles containing silica fine particles and satisfying Requirements 1) to 4) below, 1) an average sphericity of the group of particles is in a range of 0.85 to 1.00; 2) in a particle size distribution in terms of weight of the group of particles, a 10% cumulative particle size (D₁₀), a 90% cumulative particle size (D₉₀), and a 50% cumulative particle size (D₅₀) cumulated from a smaller particle size side satisfy 0.5≤(D₉₀−D₁₀)/D₅₀≤3.0 (Numerical Formula F1); 3) the particle size distribution in terms of weight of the group of particles has a distribution peak on a large particle size side; and 4) the group of particles contains irregularly-shaped particles in a range of 0.01% by number to 10% by number.

### TECHNICAL FIELD

The present invention relates to a dispersion liquid of polishing silica fine particles suitable for polishing various electronic materials such as silicon wafers, silicon carbide wafers, sapphire wafers, compound semiconductor wafers, and magnetic disks.

### BACKGROUND ART

Silica sol, fumed silica, fumed alumina, and the like have been used as polishing particles. In the manufacture of semiconductor integrated circuit-mounted substrates, aluminum wiring is formed on a silicon wafer, and an oxide film such as silica is provided thereon as an insulating film. In this case, the oxide film has unevenness due to the wiring, and thus the oxide film is polished to make it flat. In such a substrate polishing, there are demands to make the polished surface flat and free of steps or unevenness, to make the polished surface smooth and free of microscopic scratches, and to achieve a high polishing rate.

A common method for achieving a high polishing rate is to use large abrasive grains. However, if the particle size of the abrasive grains becomes too large, the flatness of the polished substrate surface tends to deteriorate. In order to obtain a high polishing rate without deteriorating the surface flatness, it is known that providing non-spherical abrasive grains, that is, providing irregularly-shaped particles as abrasive grains is effective. As a method for obtaining large irregularly-shaped particles, as disclosed in Patent Literature 1, there is known a method for obtaining large irregularly-shaped particles with a high degree of irregularity by preparing an irregularly-shaped porous gel through crushing of porous silica gel by a bead mill or the like and subjecting the irregularly-shaped porous gel to particle growth using silicic acid or the like.

As another method for obtaining a high polishing rate, it is known that the use of particles with a wide particle size distribution is also effective. As a method for producing particles with a wide particle size distribution, as disclosed in Patent Literature 2, there is known a method for obtaining silica sol with a broad particle size distribution by continuously feeding a specific silica sol to an agitated, heated reactor, growing particles while adding silicic acid to the reactor, and continuously extracting the reaction solution from an overflow line.

### CITATION LIST

### Patent Literature(s)

Patent Literature 1: JP 2018-177576 A
Patent Literature 2: JP 2012-503586 A

### SUMMARY OF THE INVENTION

### Problem(s) to be Solved by the Invention

The irregularly-shaped particles (non-spherical particles) described in Patent Literature 1 have a relatively high polishing rate when used in polishing applications, as compared with particles having a true spherical shape. However, the irregularly-shaped particles described in Patent Literature 1 have problems that the particles tend to deteriorate the surface roughness and surface waviness of the substrate after polishing and easily cause scratches. Furthermore, when irregularly-shaped particles were produced multiple times by the production method described in Patent Literature 1, it was found that the reproducibility of the particle size was poor and the polishing performance easily varied.

The silica fine particles having a true spherical shape and a broad particle size distribution described in Patent Literature 2, have a superior polishing rate compared to silica fine particles having a true spherical shape and a sharp particle size distribution. However, it has been known that even silica fine particles with a broad particle size distribution can not achieve the same level of polishing rate as irregularly-shaped silica fine particles. Furthermore, the method for producing silica fine particles having a true spherical shape and a broad particle size distribution described in Patent Literature 2 requires to simultaneously add, to a reactor, three ingredients that are seed particles (or a dispersion of seed particles), an acidic silicic acid solution, and an alkaline component while strictly controlling the conditions (temperature, pH, etc.). This results in a large load on the equipment and makes production management more complicated. According to a trace experiment actually carried out by the inventors, the particle size distribution was broad, but had tailing on a larger particle side. Therefore, even if the average particle size is desirable, the silica fine particles include some extremely large particles ranging from several hundred nanometers to microns in size, resulting in the problem of many scratches.

An object of the invention is to provide a dispersion liquid of polishing silica fine particles that exhibits an excellent polishing rate and inhibits scratches on a polishing-target substrate when used for polishing.

### Means for Solving the Problem(s)

According to an aspect of the invention, there is provided a dispersion liquid of polishing silica fine particles produced by dispersing, in a solvent, a group of particles containing silica fine particles and satisfying Requirements 1) to 4) below, a particle size in terms of specific surface area of the group of particles being in a range of 5 nm to 200 nm,
1) an average sphericity of the group of particles is in a range of 0.85 to 1.00;
2) in a particle size distribution in terms of weight of the group of particles, a 10% cumulative particle size (D₁₀), a 90% cumulative particle size (D₉₀), and a 50% cumulative particle size (D₅₀) cumulated from a smaller particle size side satisfy 0.5≤(D₉₀−D₁₀)/D₅₀≤3.0 (Numerical Formula F1);
3) the particle size distribution in terms of weight of the group of particles has a distribution peak on a large particle size side; and 4) the group of particles contains irregularly-shaped particles in a range of 0.01% by number to 10% by number.

According to another aspect of the invention, there is provided a polishing composition including the dispersion liquid of polishing silica fine particles according to the aspect of the invention, and at least one selected from a polishing accelerator, a surfactant, a heterocyclic compound, a pH adjuster, and a pH buffer.

According to still another aspect of the invention, there is provided a method for producing a dispersion liquid of polishing silica fine particles, the method including Step 1a to Step 3a below:
Step 1a: introducing an alkali and a dispersion of seed particles into a reaction vessel that is kept unheated to obtain a solution mixture;
Step 2a: after Step 1a, uniformly stirring the solution mixture, then performing heating to a temperature range of 40 degrees C. to 98 degrees C. and maintaining the solution mixture in the temperature range of 40 degrees C. to 98 degrees C., followed by performing Process A and Process B below in parallel to prepare a reaction solution, and further subjecting the reaction solution to aging in a temperature range of 40 degrees to 98 degrees C. for 20 minutes or more and 120 minutes or less,
Process A: preparing the reaction solution by continuously or intermittently adding an acidic silicic acid solution and an alkali to the reaction vessel filled with the solution mixture, and
Process B: continuously or intermittently extracting some of the reaction solution from the reaction vessel;
Step 3a: mixing the reaction solution remaining in the reaction vessel at a completion of Step 2a with the reaction solution extracted in Process B of Step 2a to obtain the dispersion liquid of polishing silica fine particles.

According to a further aspect of the invention, there is provided a method for producing a dispersion liquid of polishing silica fine particles, the method including Step 1b to Step 4b below:
Step 1b: introducing an acidic silicic acid solution and an alkali into a reaction vessel that is kept unheated to obtain a first solution mixture;
Step 2b: after Step 1b, uniformly stirring the first solution mixture, then performing heating to a temperature range of 40 degrees C. to 98 degrees C. and maintaining the first solution mixture in the temperature range of 40 degrees C. to 98 degrees C., followed by continuously or intermittently adding the acidic silicic acid solution thereto while maintaining the temperature range of 40 degrees C. to 98 degrees C. to obtain a second solution mixture;
Step 3b: after Step 2b, performing Process A and Process B below in parallel,
Process A: continuously or intermittently adding an acidic silicic acid solution and an alkali to the reaction vessel filled with the second solution mixture to prepare a reaction solution, and
Process B: continuously or intermittently extracting some of the reaction solution from the reaction vessel of Process A;
Step 4b: subjecting the reaction solution obtained in Process A and Process B of Step 3b to aging in a temperature range of 40 degrees C. to 98 degrees C. for 20 minutes or more and 120 minute or less, and adding the reaction solution extracted in Process B of Step 3b thereto then mixing to obtain the dispersion liquid of polishing silica fine particles.

According to the aspects of the invention, it is possible to provide a dispersion liquid of polishing silica fine particles that exhibits an excellent polishing rate and inhibits scratches on a polishing-target substrate when used for polishing, and a production method of the same.

### DESCRIPTION OF EMBODIMENT(S)

### Dispersion Liquid of Polishing Silica Fine Particles

First, a dispersion liquid of polishing silica fine particles according to an exemplary embodiment will be described,

The dispersion liquid of polishing silica fine particles according to the exemplary embodiment is produced by dispersing, in a solvent, a group of particles including silica fine particles as polishing abrasive grains. The group of particles needs to satisfy Requirements 1 to 4 below.

Herein, the “dispersion liquid of polishing silica fine particles” is occasionally referred to simply as a “dispersion.” In addition, the “group of particles including silica fine particles” dispersed in the dispersion liquid of polishing silica fine particles is occasionally referred to simply as a “group of particles”.

The reasons why the dispersion liquid of polishing silica fine particles according to the exemplary embodiment exhibits an excellent polishing rate, can improve the surface roughness of a polishing-target substrate, and can inhibit the occurrence of scratches on the polishing-target substrate when applied to polishing applications are not necessarily clear, but the inventors presume as follows.

The group of particles in the exemplary embodiment has a broad particle size distribution. The polishing rate can thus be improved compared to conventional polishing abrasive grains. The particle size distribution has a peak on a large particle size side, that is, there is no tailing on the large particle size side, and thus extremely large particles are not included. Furthermore, since the group of particles in the exemplary embodiment has a true spherical shape, the surface roughness is improved and the occurrence of scratches is inhibited. Moreover, the group of particles in the exemplary embodiment mainly contains silica fine particles of a true spherical shape, and also contains trace amounts of irregularly-shaped silica fine particles. These irregularly-shaped silica fine particles can improve the polishing rate. Since the amount of these irregularly-shaped silica fine particles is very small, they have little adverse effect on the surface roughness or scratches. The inventors presume that the effects of the invention are achieved in the above manner.

In a first production method for the dispersion liquid of polishing silica fine particles according to the exemplary embodiment, seed particles are added to an unheated reaction vessel on charging, and thereafter, seed particles are not added to the reaction vessel. This method can prevent the seed particles from aggregating, and since the seed particles are not added during mixing, the load on the manufacturing equipment and the load on process management can be reduced, allowing the dispersion liquid of polishing silica fine particles to be produced efficiently. The inventors presume that the effects of the invention are achieved in the above manner.

In a second production method for the dispersion liquid of polishing silica fine particles according to the exemplary embodiment, an acidic silicic acid solution is added to an unheated reaction vessel on charging. This method can prevent the acidic silicic acid solution from drying, and since no seed particles are added during mixing in Step 3b, the load on the manufacturing equipment and the load on process management can be reduced, allowing the dispersion liquid of polishing silica fine particles to be produced efficiently. The inventors presume that the effects of the invention are achieved in the above manner.

The requirements or characteristics of the dispersion liquid of polishing silica fine particles according to the exemplary embodiment, namely, a particle size in terms of specific surface area, an average sphericity, a particle size distribution in terms of weight, a peak of a particle size distribution, an irregularly-shaped particle proportion, and a coefficient of variation of a particle size distribution area, will be described below. Unless otherwise specified, the description about the effect or performance provided by each of the requirements or characteristics means the effect or performance when the dispersion liquid of polishing silica fine particles according to the exemplary embodiment is applied to polishing purposes.

### Particle Size in Terms of Specific Surface Area

The particle size in terms of specific surface area of the group of particles according to the exemplary embodiment needs to be in a range of 5 nm to 200 nm. Using the dispersion liquid of polishing silica fine particles according to the exemplary embodiment, whose particle size in terms of specific surface area falls within the above range, as polishing silica fine particles for polishing silicon wafers, magnetic disks, or semiconductor substrates, results in a high polishing rate, inhibits the occurrence of scratches on a polishing target, and makes a surface of the polishing target smoother. If the particle size is less than 5 nm, it is highly unlikely that the polishing rate will be practically sufficient. If the particle size exceeds 200 nm, it is highly likely that scratches occur on a polishing-target substrate.

The particle size in terms of specific surface area of the group of particles is preferably in a range of 10 nm to 150 nm, more preferably in a range of 20 nm to 100 nm.

### Average Sphericity

The average sphericity of the group of particles according to the exemplary embodiment needs to be in a range of 0.85 to 1.00 (Requirement 1).

The group of particles includes true spherical shape particles. In the exemplary embodiment, the true spherical shape particles refer to particles having an average sphericity in the range of 0.85 to 1.00. The average sphericity can be calculated by calculating a short diameter/long diameter value of each silica fine particle from the observation result of an electron microscope photograph, which will be described later, and then calculating the simple average.

When the dispersion liquid of polishing silica fine particles according to the exemplary embodiment, in which the group of particles having an average sphericity value of 0.85 or more is dispersed in a solvent, is applied to a polishing purpose, the surface roughness of the polishing substrate can be smoothed and the occurrence of scratches can be inhibited. Even if the group of particles contains the irregularly-shaped particles in a range of 0.01% by number to 10.0% by number, scratches can be inhibited as long as the average sphericity of the group of particles is within the above range. The function and effect of the irregularly-shaped particles (irregularly-shaped silica particles) included in the group of particles are described later.

The average sphericity of the group of particles is preferably in a range of 0.90 to 1.00, and more preferably in a range of 0.92 to 1.00.

A specific method for measuring the average sphericity of the group of particles according to the exemplary embodiment is as described below.

### Particle Size Distribution in Terms of Weight

In the particle size distribution in terms of weight of the group of particles according to the exemplary embodiment, a 10% cumulative particle size (D₁₀), a 90% cumulative particle size (D₉₀), and a 50% cumulative particle size (D₅₀) cumulated from a smaller particle size side need to satisfy Numerical Formula (F1) below (Requirement 2).

$$0.5 \leq ( {D}_{90} - {D}_{10} ) / {D}_{50} \leq 3. \qquad ( F1 )$$

The value of (D₉₀−D₁₀)/D₅₀ in Numerical Formula (F1) indicates an extent of the particle size distribution, and the larger the value of (D₉₀−D₁₀)/D₅₀, the wider the particle size distribution. A large value of (D₉₀−D₁₀)/D₅₀ indicates that the particle size includes both small and large particles. Here, larger particles exhibit a high polishing rate, and smaller particles exhibit a scratch repair effect. The dispersion liquid of silica fine particles with such a particle size distribution can achieve both the high polishing rate and the inhibition of scratch occurrence.

If the value of (D₉₀−D₁₀)/D₅₀ is in a range of 0.5 to 3.0, it can be said that the particle size distribution is sufficiently broad and contains an appropriate amount of small and large particles. Typically, the larger the particle size, the higher the polishing rate. However, larger particles are likely to cause scratches on a substrate. If the particle size distribution satisfies the above range, the content of large particles and small particles is well balanced, and scratches caused by the large particles can be repaired by the small particles, which is preferable.

The value of (D₉₀−D₁₀)/D₅₀ is preferably in a range of 0.6 to 2.0, more preferably in a range of 0.8 to 1.8.

### Peak of Particle Size Distribution

A particle size distribution in terms of weight of the group of particles according to the exemplary embodiment needs to have a distribution peak on the large particle size side (Requirement 3).

Here, having a distribution peak on the large particle size side means that the distribution peak is present on the large particle size side from D₅₀ (the 50% cumulative particle size cumulated from the smaller particle size side) in the particle size distribution in terms of weight.

When the particle size distribution has a peak on the large particle size side, there is no tailing on the large particle size side in that particle size distribution. In contrast, a distribution in which there is a tailing on the large particle size side contains extremely large particles. Typically, the larger the particle size, the faster the polishing rate, but the more likely it is that scratches will occur and the surface roughness will deteriorate. The extremely large particles are prone to causing irreparable scratches. Therefore, particles having a distribution that has a peak on the large particle size side but does not tail on the large particle size side are likely to inhibit fatal scratches.

Furthermore, combining Requirement 2 with Requirement 3 can achieve the improvement in polishing rate, surface roughness, and the like, because scratches caused by the peak on the large particle size side are repaired by small particles that have a slow polishing rate but have a function of smoothing the surface. The particle size (D₅₀) in the particle size distribution in terms of weight, which is a criterion for having a distribution peak on the large particle size side, is preferably D₆₀.

### Irregularly-Shaped Particle Proportion

The group of particles according to the exemplary embodiment needs to contain 0.01% by number or more and 10.0% by number or less of irregularly-shaped particles that do not have a true spherical shape (Requirement 4).

The irregularly-shaped particle that does not have the true spherical shape refers to a particle having a short diameter/long diameter value of less than 0.85, and can be calculated from the observation result of an electron microscope photograph described later. Such irregularly-shaped particles typically exhibit a high polishing rate, but are prone to causing scratches on a substrate surface. Setting the irregularly-shaped particle proportion (the number of irregularly-shaped particles/the total number of particles×100) in the range of 0.01% by number to 10.0% by number allows the group of particles according to the exemplary embodiment used as polishing abrasive grains to provide advantages as follows: the irregularly-shaped particles contained within the above range (% by number) contribute to a high polishing rate, and the remaining true spherical shape particles inhibit the occurrence of scratches on the substrate surface and repair the scratches on the substrate surface. It is thus possible to achieve both the high polishing rate and the smoothness of the surface of the polishing-target substrate after polishing. If the proportion of irregularly-shaped particles in the group of particles is less than 0.01% by number, the irregularly-shaped particles will not be effective in improving the polishing rate. If the proportion of irregularly-shaped particles in the group of particles exceeds 10.0% by number, scratches caused by the irregularly-shaped particles are likely to increase. The irregularly-shaped particle proportion is preferably in a range of 0.05% by number to 10.0% by number, more preferably in a range of 0.10% by number to 10.0% by number, and particularly preferably in a range of 1.0% by number to 10.0% by number. The irregularly-shaped particles in the exemplary embodiment refer to irregularly-shaped silica particles. The irregularly-shaped particle proportion may be in a range of 0.01% by number to 8.0% by number, or in a range of 0.01% by number to 5.0% by number.

The irregularly-shaped particle proportion can be measured as follows. The dispersion liquid of silica fine particles is observed in a photograph or image taken at a magnification of 200,000 times using an electron microscope. Specifically, a photograph was taken so that 200 or more particles were included in the same field of view, and the short diameter/long diameter value of each of the 200 or more silica fine particles in the photograph or image obtained was measured. The number (n) of particles with a short diameter/long diameter value of less than 0.85 (irregularly-shaped particles) was calculated, and the irregularly-shaped particle proportion was calculated using the following expression.

$$Irregularly - Shaped Particle Proportion = ( n / 200 ) \times 100 [ \% by number ]$$

The proportion of irregularly-shaped particles in the group of particles according to the exemplary embodiment is preferably in a range of 1.3% by number to 9.0% by number, more preferably in a range of 1.8% by number to 8.0% by number, and particularly preferably in a range of 2.0% by number to 7.0% by number.

### Coefficient of Variation of Particle Size Distribution Area

In the exemplary embodiment, it is preferable that the group of particles further satisfies Requirement 5 below.
5) In a particle size distribution obtained from the particle size/the number of particles of the group of particles, a particle size range from a 1% cumulative particle size (D₁) to a 99% cumulative particle size (D₉₉), cumulated from the smaller particle size side, is divided into six equal parts, and the particle size ranges are designated as S1, S2, S3, S4, S5, and S6, respectively. A coefficient of variation (CV value) of the particle size distribution area corresponding to each particle size range is in a range of 20.0% to 70.0%.

Since the particle size distribution of ordinary silica sol shows a normal distribution, the CV value is a high value exceeding 70.0%. A CV value in the range of 20.0% to 70.0% means that the areas of S1 to S6 are relatively uniform, and the shape of the particle size distribution is roughly trapezoidal or rectangular while it has a peak on the large particle size side. Such a particle size distribution relatively uniformly includes large particles achieving a fast polishing rate, small particles inhibiting scratches, and medium particles that have a good balance between the polishing rate and the scratch inhibition, thus achieving both the high polishing rate and the inhibition of scratch. If the CV value is less than 20.0%, it is practically difficult to obtain such a particle size distribution. If the CV value exceeds 70.0%, the polishing rate tends to be slow since the distribution becomes close to the normal distribution.

The CV value is more preferably in a range of 22.0% to 65.0%, and particularly preferably in a range of 25.0% to 62.0%.

### Silica/Polyethyleneimine [Mass Ratio] at Equivalence Point

In the exemplary embodiment, it is preferable that the dispersion liquid of polishing silica fine particles further satisfies Requirement 6 below.
6) In streaming potential measurement (using cationic polymeric polyethyleneimine having a weight average molecular weight of 600 as a titration reagent), the mass ratio of polyethyleneimine to silica at an equivalence point is in a range of 1.0 to 1.9.

In the dispersion liquid of silica fine particles according to the exemplary embodiment, it is preferable that a ratio (V/SiO₂) of an amount (V [g]) of addition of a cationic solid content (cationic polymeric polyethyleneimine having a weight average molecular weight of 600) in a cation titrant at a knick to a SiO₂ solid content [g] is in a range of 1.0 to 1.9.

Using such a dispersion liquid of silica fine particles, in which V/SiO₂ is in the range of 1.0 to 1.9, for polishing purposes results in a good polishing rate.

In a case of V/SiO₂ of less than 1.0, if a cationic additive is mixed in a polishing solution and used for polishing, the dispersion stability of the silica fine particles may deteriorate to decrease the polishing rate, which is not preferable. In a case of V/SiO₂ exceeding 1.9, if a cationic additive is mixed in a polishing solution and used for polishing, the cationic additive adsorbed in excess to the silica fine particles may interfere with polishing to decrease the polishing rate, which is not preferable.

More preferably, V/SiO₂ is in a range of 1.3 to 1.8. V/SiO₂ is determined by cation titration.

### Silica Fine Particles

It can be confirmed, for example, by an inductively coupled plasma emission spectrometer (ICP device) that the silica fine particles in the exemplary embodiment are composed of silica. In a 30 mL zirconia bowl with a lid, 1 g of a water dispersion containing the silica fine particles according to the exemplary embodiment was collected, dried (at 200 degrees C. for 20 minutes), and then 2 g of Na₂O₂ and 1 g of NaOH were added and melted for 15 minutes. Further, 10 mL of 98 mass % sulfuric acid and 10 mL of pure water were added to dissolve, and then the solution was diluted with pure water to a total volume of 500 mL to prepare a sample. For the obtained sample, the content of silicon can be measured using an ICP device (ICPS-8100, analysis software ICPS-8000 manufactured by Shimadzu Corporation).

The group of particles according to the exemplary embodiment is composed of silica, but may contain 10 mass % or less of components other than silica. Exemplary components other than silica include Al, Ti, Fe, Ca, Mg, Cr, Ni, Cu, Zn, K, and Na, and oxides thereof.

As described above, for example, an ICP device may be used to confirm that the group of particles of the exemplary embodiment of the invention is composed of silica.

The content of components other than silica that may be contained in the group of particles of the exemplary embodiment of the invention can be identified and quantified by, for example, an inductively coupled plasma emission spectrometer. It should be noted that Ni, Cu, K and Na can be identified and quantified using an atomic absorption spectrophotometer.

### Solvent

As described above, the dispersion according to the exemplary embodiment is produced by dispersing the group of particles according to the exemplary embodiment in a solvent.

Examples of the solvent include water, alcohols such as methyl alcohol, ethyl alcohol, and isopropyl alcohol, and water-soluble organic solvents such as ethers, esters, and ketones. The solvent may be a mixed solvent composed of water and an organic solvent.

The content of the group of particles contained in the dispersion of the exemplary embodiment is preferably in a range of 1% by mass to 50% by mass, and more preferably in a range of 10% by mass to 50% by mass.

Regarding the content of the group of particles, the dispersion liquid of silica fine particles was subjected to loss on ignition at 1,000 degrees C., the obtained solid content was weighed, and the concentration obtained by subtracting, from the solid content, a separately calculated alkali content converted into an oxide (Na₂O or the like) was defined as the content of the group of particles according to the exemplary embodiment.

### Polishing Composition

A polishing composition according to the exemplary embodiment will be described.

The polishing composition according to the exemplary embodiment contains a dispersion liquid of polishing silica fine particles according to the exemplary embodiment or a group of particles according to the exemplary embodiment and a solvent, and further contains components that impart necessary performance including polishing performance.

Exemplary components that impart necessary performance include polishing accelerators, surfactants, hydrophilic compounds, heterocyclic compounds, pH adjusters, and pH buffers. The polishing composition may contain only one or two or more of these components as the components that impart necessary performance.

The polishing composition according to the exemplary embodiment is also referred to as a “polishing slurry”.

The dispersion liquid of polishing silica fine particles or polishing composition according to the exemplary embodiment can be applied, for example, as a CMP slurry to polish semiconductor wafers such as silicon wafers, or to polish substrates for hard disk drives, liquid crystal glass, sapphire substrates, compound semiconductors, GaN substrates, SiC substrates, or the like.

Exemplary polishing accelerators include acids such as sulfuric acid, nitric acid, phosphoric acid, oxalic acid, and hydrofluoric acid, as well as sodium, potassium, and ammonium salts of these acids and mixtures thereof. The composition according to the exemplary embodiment of the invention containing these polishing accelerators results in a flat polished surface, because when a polishing target containing multiple components is polished, the polishing rate of a specific component of the polishing target is promoted.

When the polishing composition according to the exemplary embodiment contains the polishing accelerator(s), the content thereof is preferably in a range of 0.1% by mass to 10% by mass, and more preferably in a range of 0.5% by mass to 5% by mass.

As at least one of the surfactant or the hydrophilic compound, a cationic, anionic, nonionic or amphoteric surfactant or a hydrophilic compound may be added to improve the dispersibility and stability of the polishing composition.

Both the surfactant and the hydrophilic compound have the effect of decreasing a contact angle with a surface to be polished, and thus promote uniform polishing. At least one of the surfactant or the hydrophilic compound can be selected, for example, from the following groups.

The anionic surfactant is exemplified by carboxylate, sulfonate, sulfuric acid ester salt, and phosphoric acid ester salt. The carboxylate is exemplified by soap, N-acylamino acid salt, polyoxyethylene or polyoxypropylene alkyl ether carboxylate, and acylated peptide. The sulfonate is exemplified by alkyl sulfonate, alkyl benzene and alkyl naphthalene sulfonate, naphthalene sulfonate, sulfosuccinate, α-olefin sulfonate, and N-acylsulfonate.

The sulfuric acid ester salt is exemplified by sulfated oil, alkyl sulfate, alkyl ether sulfate, polyoxyethylene or polyoxypropylene alkyl allyl ether sulfate, and alkylamide sulfate. The phosphoric acid ester salt is exemplified by alkyl phosphate, polyoxyethylene or polyoxypropylene alkyl allyl ether phosphate.

The cationic surfactant is exemplified by aliphatic amine salt, aliphatic quaternary ammonium salt, benzalkonium chloride, benzethonium chloride, pyridinium salt, and imidazolinium salt. The amphoteric surfactant is exemplified by those of carboxybetaine-type, sulfobetaine-type, aminocarboxylate, imidazolinium betaine, lecithin, and alkylamine oxide.

Exemplary nonionic surfactants include those of ether-type, ether ester-type, ester-type, and nitrogen containing-type. The ether-type ones are exemplified by polyoxyethylene alkyl and alkyl phenyl ethers, alkylallylformaldehyde-condensed polyoxyethylene ether, polyoxyethylene polyoxypropylene block polymer, and polyoxyethylene polyoxypropylene alkyl ether. The ether ester-type ones are exemplified by polyoxyethylene ether of glycerin ester, polyoxyethylene ether of sorbitan ester, and polyoxyethylene ether of sorbitol ester. The ester-type ones are exemplified by polyethylene glycol fatty acid ester, glycerin ester, polyglycerin ester, sorbitan ester, propylene glycol ester, and sucrose ester. The nitrogen containing-type ones are exemplified by fatty acid alkanolamide, polyoxyethylene fatty acid amide, and polyoxyethylene alkylamide. Still other examples include fluorine-containing surfactant.

The surfactant is preferably the anionic surfactant or the nonionic surfactant. The salt is exemplified by ammonium salt, potassium salt, and sodium salt. The ammonium salt and potassium salt are particularly preferable.

Still other surfactants and hydrophilic compound are exemplified by esters such as glycerin ester, sorbitan ester and alanine ethyl ester; ethers such as polyethylene glycol, polypropylene glycol, polytetramethylene glycol, polyethylene glycol alkyl ether, polyethylene glycol alkenyl ether, alkylpolyethylene glycol, alkyl polyethylene glycol alkyl ether, alkylpolyethylene glycol alkenyl ether, alkenylpolyethylene glycol, alkenylpolyethylene glycol alkyl ether, alkenylpolyethylene glycol alkenyl ether, polypropylene glycol alkyl ether, polypropylene glycol alkenyl ether, alkylpolypropylene glycol, alkylpolypropylene glycol alkyl ether, alkylpolypropylene glycol alkenyl ether, and alkenylpolypropylene glycol; polysaccharides such as arginic acid, pectic acid, carboxymethyl cellulose, curdlan, and pullulan; amino acid salts such as glycine ammonium salt and glycine sodium salt; polycarboxylic acids and salts thereof such as polyaspartic acid, polyglutamic acid, polylysine, polymalic acid, polymethacrylic acid, ammonium polymethacrylate, sodium polymethacrylate, polyamic acid, polymaleic acid, polyitaconic acid, polyfumaric acid, poly(p-styrenecarboxylic acid), polyacrylic acid, polyacrylamide, aminopolyacrylamide, ammonium polyacrylate, sodium polyacrylate, polyamic acid, ammonium polyamidate, sodium polyamidate and polyglyoxylic acid; vinyl-based polymers such as polyvinyl alcohol, polyvinylpyrrolidone and polyacrolein; sulfonic acids and salts thereof such as ammonium methyltaurinate, sodium methyltaurinate, sodium methylsulfate, ammonium ethylsulfate, ammonium butylsulfate, sodium vinylsulfonate, sodium 1-allylsulfonate, sodium 2-allylsulfonate, sodium methoxymethylsulfonate, ammonium ethoxymethylsulfonate, and sodium 3-ethoxylpropylsulfonate; and amides such as propionamide, acrylamide, methylurea, nicotinamide, succinamide and sulfanilamide.

When the polishing-target base to be used is a glass substrate or the like, any of these surfactants may suitably be used. For a silicon substrate for semiconductor integrated circuit or the like, where the effects of contamination by alkali metals, alkaline earth metals, halides, or the like must be avoided, it is desirable to use an acid or ammonium salt-based surfactant.

When the polishing composition according to the exemplary embodiment contains at least one of the surfactant or the hydrophilic compound, the total content thereof is preferably 0.001 g or more and 10 g or less in 1 L of the polishing composition according to the exemplary embodiment, more preferably 0.01 g or more and 5 g or less, and particularly preferably 0.1 g or more and 3 g or less.

The surfactant or hydrophilic compound may be used alone or in combination of two or more thereof. In addition, ones of different types may be used in combination.

When the polishing-target base contains a metal, the polishing composition according to the exemplary embodiment may contain a heterocyclic compound, for the purpose of inhibiting erosion of the polishing-target base, in expectation of forming a passivation layer or a dissolution inhibiting layer on the metal. The “heterocyclic compound” refers to a compound having a heterocycle that contains one or more hetero atoms. The hetero atom means an atom other than carbon atom and hydrogen atom. The heterocycle means a cyclic compound having at least one hetero atom. The hetero atom means only an atom that forms a constitutive moiety of the ring system of the heterocycle, but does not mean an atom that resides outside the ring system, an atom that resides separately from the ring system while placing in between at least one non-conjugative single bond, and an atom that forms a part of a substituent on the ring system. The hetero atom is preferably exemplified by, but not limited to, nitrogen atom, sulfur atom, oxygen atom, selenium atom, tellurium atom, phosphorus atom, silicon atom, and boron atom. Examples usable as the heterocyclic compound include imidazole, benzotriazole, benzothiazole, and tetrazole. More specific examples thereof include 1,2,3,4-tetrazole, 5-amino-1,2,3,4-tetrazole, 5-methyl-1,2,3,4-tetrazole, 1,2,3-triazole, 4-amino-1,2,3-triazole, 4,5-diamino-1,2,3-triazole, 1,2,4-triazole, 3-amino-1,2,4-triazole, and 3,5-diamino-1,2,4-triazole, but are not limited thereto.

When the polishing composition according to the exemplary embodiment contains a heterocyclic compound, the content thereof is preferably in a range of 0.001% by mass to 1.0% by mass, more preferably in a range of 0.001% by mass to 0.7% by mass, and still more preferably in a range of 0.002% by mass to 0.4% by mass.

For the purpose of enhancing the effect of the individual additive described above, an acid or a base may optionally be added to regulate the pH of the polishing composition.

To control the polishing composition according to the exemplary embodiment to pH7 or above, an alkaline pH adjuster is used. Desirably used are sodium hydroxide, aqueous ammonia, ammonium carbonate, and amines such as ethylamine, methylamine, trioethylamine, and tetramethylamine.

To control the polishing composition according to the exemplary embodiment to less than pH7, an acidic pH adjuster is used. Examples thereof include hydroxy acids such as lactic acid, citric acid, malic acid, tartaric acid and glyceric acid.

To keep the pH value of the polishing composition according to the exemplary embodiment constant, a pH buffer may be used. Examples usable as the pH buffer include phosphate and borate such as ammonium dihydrogen phosphate, diammonium hydrogen phosphate; and ammonium tetraborate tetrahydrate; and organic acid.

The concentration of polishing particles in the polishing composition according to the exemplary embodiment is preferably in a range of 0.5% by mass to 50% by mass, and more preferably in a range of 5% by mass to 30% by mass. A concentration of less than 0.5% by mass is too low depending on the type of the substrate or insulating film, resulting in a slow polishing rate and a problem in productivity. If the concentration of polishing particles exceeds 50% by mass, the stability as the abrasive becomes insufficient, and the polishing rate and polishing efficiency no longer improve. Also, during the process of supplying the dispersion for polishing, dried matter may be generated and adhere to the polishing target, which may cause scratches.

### First Production Method for Dispersion Liquid of Polishing Silica Fine Particles

The first production method for the dispersion liquid of polishing silica fine particles according to the exemplary embodiment will be described.

The dispersion liquid of polishing silica fine particles according to the exemplary embodiment described above can be preferably produced by the first production method for the dispersion liquid of polishing silica fine particles according to the exemplary embodiment.

The first production method for the dispersion according to the exemplary embodiment includes Steps 1a to 3a below.

### Step 1a

In Step 1a, an alkali and a dispersion of seed particles are introduced as raw materials into a reaction vessel that is kept unheated, and a solvent is added as necessary to prepare a solution mixture.

When these raw materials are introduced into the reaction vessel, splashing occurs on a bottom surface or inner wall of the reaction vessel or on the solution surface (the solution surfaces of the dispersion of seed particles and the alkali introduced). If the raw materials are introduced into a heated reaction vessel, the splashed raw materials easily dry to become coarse aggregates, which may cause a problem. If the raw materials are introduced gradually enough to avoid splashing, the mixing time will be long and the economic efficiency will be poor. In addition, when the dispersion of seed particles and the alkali are added to a heated reaction vessel, the dispersion of seed particles and the alkali are heated from the beginning of the addition, whereby the seed particles are likely to aggregate at an early stage.

The “unheated” means that no operation for increasing the temperature of the reaction vessel is performed. If the temperature of the unheated reaction vessel exceeds 40 degrees C. due to seasonal high temperatures or the like, it is recommended that the reaction vessel be cooled to have a temperature of less than 40 degrees C.

Preferably, the temperatures of the dispersion of seed particles and the alkali at the stage of introducing them into the reaction vessel are both less than 40 degrees C.

As the dispersion of seed particles, the dispersion liquid of silica fine particles is used, as described below.

The dispersion of seed particles and the alkali are added so that the molar ratio of silica to alkali (in terms of oxide) in the solution mixture is in a range of 20 to 160, and further a solvent is added as needed for adjustment so that the silica concentration in the solution mixture is in a range of 1% by mass to 15% by mass.

Here, the molar ratio of silica to alkali (in terms of oxide) is represented by molar ratio=[moles of SiO₂]/[moles of A₂O], where A represents an alkali metal, ammonia, an organic alkali, water glass, or the like. If the molar ratio of silica to alkali (in terms of oxide) is less than 20, the amount of alkali will be excessive, causing the ionic strength in the solution mixture to be excessively high. This causes the silica fine particles to aggregate, makes it impossible to obtain particles with a true spherical shape, and makes it more likely that sedimentation will occur. Even if no sedimentation occurs, the increase in aggregates of silica fine particles makes it difficult to obtain monodispersed silica sol.

If the molar ratio of silica to alkali (in terms of oxide) exceeds 160, the alkali concentration in the solution mixture will be low. When the acidic silicic acid solution is added in a subsequent Step 2a, the pH of the reaction solution will be significantly low. As a result, the added acidic silicic acid solution fails to deposit on seed particle surfaces, and self-nucleation occurs due to silicic acid, making it difficult to obtain silica sol with a desired particle size. The molar ratio of silica to alkali (in terms of oxide) is preferably in a range of 40 to 140, more preferably in a range of 50 to 130, and particularly preferably in a range of 60 to 120.

If the silica concentration in the solution mixture is less than 1% by mass, it is easy to obtain monodispersed silica fine particles. However, because of a low silica concentration in the solution mixture, production is not efficient and is uneconomical. If the silica concentration exceeds 15% by mass, the silica fine particles are likely to aggregate during mixing, making it difficult to obtain monodispersed silica fine particles. The silica concentration in the solution mixture is more preferably in a range of 2% by mass to 10% by mass, and particularly preferably in a range of 3% by mass to 8% by mass.

When the molar ratio of silica to alkali (in terms of oxide) and the silica concentration in the solution mixture are within the above-mentioned ranges, most of the seed particles avoid aggregation, but some of them aggregate and become irregularly-shaped particles. As a result, the silica fine particles in the dispersion liquid of silica fine particles according to the exemplary embodiment are mostly particles having a true spherical shape, but include irregularly-shaped particles in a range of 1.0% by number to 10% by number.

### Dispersion of Seed Particles

As the dispersion of seed particles used in Step 1a, the dispersion liquid of silica fine particles can be used. In this case, the seed particles are silica fine particles.

Here, the size of the seed particles (particle size in terms of specific surface area) is not particularly limited, because any size can be selected depending on the particle size of the dispersion liquid of silica fine particles to be finally prepared. A size smaller than the size of the silica fine particles to be finally prepared is typically selected. When the dispersion liquid of silica fine particles to be finally prepared is used for polishing purposes, the particle size of the seed particles in terms of specific surface area is preferably selected in a range of 5 nm to 200 nm.

The silica concentration in the dispersion of seed particles is preferably in a range of 1% by mass to 50% by mass, and more preferably in a range of 3% by mass to 50% by mass. If the silica concentration is less than 1% by mass, the production efficiency in Steps 1a to 3a decreases, which is unfavorable. If the silica concentration exceeds 50% by mass, the stability of the silica fine particles decreases, and for example, aggregated particles tend to occur, which is unfavorable.

### Alkali

Examples of the alkali added in Step 1a include alkali silicates such as sodium silicate (water glass) and potassium silicate; alkali metals such as sodium hydroxide, potassium hydroxide, and lithium hydroxide; ammonia; and organic alkalis such as organic amines. Here, the alkali is typically added as an aqueous alkali solution. The alkali concentration of the aqueous alkali solution is not particularly limited, but is typically in a range of 1% by mass to 50% by mass.

### Solvent

Exemplary solvents that may be added in Step 1a, if necessary, include water, ion-exchanged water, pure water, ultrapure water, a mixed solvent containing water and a water-soluble organic solvent, and a water-soluble organic solvent.

### Step 2a

In Step 2a, the solution mixture prepared in Step 1a is stirred uniformly, heated, and maintained at a temperature of 40 degrees C. or more and 98 degrees C. or less for a certain period of time. Then, Processes A and B as below are performed in parallel.
Process A: A reaction solution is prepared by continuously or intermittently adding an acidic silicic acid solution and an alkali to the reaction vessel filled with the solution mixture.
Process B: Some of the reaction solution is extracted from the reaction vessel continuously or intermittently.

### Retention Temperature and Retention Time

In Step 2a, the solution mixture obtained in Step 1a is heated to a temperature of 40 degrees C. or more and 98 degrees C. or less while stirring, and maintained in the same temperature range for a certain period of time. Here, the retention time is preferably in a range of 20 minutes to 120 minutes, and more preferably in a range of 30 minutes to 90 minutes. Maintaining this temperature activates the surfaces of the seed particles, which is suitable for particle growth in the subsequent process. Furthermore, maintaining this temperature allows the solution mixture to be sufficiently homogenized. If the retention time is less than 20 minutes, surface activation is insufficient and the particle growth provided by the subsequent addition of the acidic silicic acid solution is likely to be non-uniform, which may cause the self-nucleation by silicic acid. If the retention time exceeds 120 minutes, the surface activation of the seed particles does not progress further. Instead, such a long retention time reduces production efficiency and economic efficiency. The retention temperature is preferably in the above-described range of 40 degrees C. to 98 degrees C. The temperature is desirably kept constant within this temperature range.

Subsequently, Process A and Process B are performed in parallel. Process A is performed to grow the seed particles to a desired size by adding the acidic silicic acid solution (here, the addition of the alkali for the purpose of maintaining the pH of the reaction solution and the addition of the acidic silicic acid solution for the purpose of growing particles are performed in parallel). Process B is performed to extract some of the reaction solution from the reaction vessel. Since the particle growth reaction of the seed particles progresses upon the addition of the acidic silicic acid solution, after the start of addition of the acidic silicic acid solution, the “solution mixture” is referred to as the “reaction solution”.

Mixing the reaction solution extracted in Process B with the reaction solution remaining in the reaction vessel in Step 3a can result in a dispersion liquid of silica fine particles with a broader particle size distribution (wider particle size distribution range).

### Acidic Silicic Acid Solution

As the acidic silicic acid solution, it is possible to use one obtained by dealkalizing an aqueous alkali silicate solution with a cation exchange resin. The concentration of the acidic silicic acid solution is, in terms of SiO₂, preferably in a range of 0.1% by mass to 10% by mass, more preferably in a range of 1% by mass to 7% by mass. The pH of the acidic silicic acid solution is preferably in a range of 1 to 3.

Regarding the amount (total amount) of the acidic silicic acid solution added to the solution mixture or reaction solution in Step 2a, when the amount (the number of moles) of SiO₂ contained in the acidic silicic acid solution is represented by Ma and the number of moles of SiO₂ contained in the solution mixture is represented by Ms, a value of Ma/Ms is preferably in a range of 1 to 20. The value of Ma/Ms is more preferably in a range of 2 to 15.

If the value of Ma/Ms is less than 1, the growth of the silica fine particles in the dispersion liquid of silica fine particles obtained by the production method according to the exemplary embodiment will be slow not to provide a broad distribution, resulting in an insufficient polishing rate even when used as an abrasive. If the value of Ma/Ms exceeds 20, the particle size of the silica fine particles in the dispersion liquid of silica fine particles obtained by the production method according to the exemplary embodiment becomes excessively large. When such silica fine particles are used as an abrasive, at least scratches on a polishing-target substrate may occur significantly, which is undesirable. Furthermore, if the value of Ma/Ms exceeds 20, the mixing time becomes extremely long, which reduces the economic efficiency.

### Reaction Temperature

The temperature of the solution mixture or reaction solution when the acidic silicic acid solution is added to the solution mixture or reaction solution is preferably in a range of 40 degrees to 98 degrees. If the temperature of the solution mixture or reaction solution is less than 40 degrees C., the added acidic silicic acid solution will be difficult to dissolve and therefore will be difficult to deposit on the seed particle surfaces. This causes self-nucleation by silicic acid, making it impossible to obtain particles with a desired size. If the temperature of the solution mixture or reaction solution exceeds 98 degrees C., the added acidic silicic acid solution will dissolve sufficiently and the seed particles will grow. However, an excessively high temperature of the solution mixture or reaction solution can be problematic in terms of energy efficiency and safety. More preferably, the temperature of the solution mixture or reaction solution when the acidic silicic acid solution is added thereto is in a range of 50 degrees C. to 98 degrees C.

### Rate of Addition of Acidic Silicic Acid Solution

In Process A of Step 2a of the exemplary embodiment, the rate of addition of the acidic silicic acid solution to the reaction vessel filled with the solution mixture is expressed as silica dry-g [g] in the acidic silicic acid solution added per minute per mass [g] of silica particles contained in the solution in the reaction vessel. Here, the unit of the rate at which the acidic silicic acid solution is added to the liquid is [g/min·g]. The term “solution” is a general term for the liquid that fills the reaction vessel for convenience. Before the start of Process A, the reaction vessel is filled only with the solution mixture, and once the addition of the acidic silicic acid solution begins, the particle growth reaction progresses and the reaction solution is provided. The solution includes the solution mixture or the reaction solution, and means the liquid in the reaction vessel.

The rate at which the acidic silicic acid solution is added to the liquid is preferably in a range of 0.0001 g/min·g to 0.05 g/min·g. If the rate is within the above range, the acidic silicic acid solution added for the purpose of particle growth is dissolved by alkali in the solution mixture and deposited on seed particle surfaces, thereby promoting the growth of the seed particles. If the rate at which the acidic silicic acid solution is added to the liquid is less than 0.0001 g/min·g, the mixing time becomes too long for practical use, reducing the practicality and economic efficiency. If the rate at which the acidic silicic acid solution is added to the liquid exceeds 0.05 g/min·g, self-nucleation may proceed without the silicic acid being deposited on the particle surfaces, which is unfavorable.

The rate at which the acidic silicic acid solution is added to the liquid is more preferably in a range of 0.0005 g/min·g to 0.02 g/min·g, and particularly preferably in a range of 0.002 g/min·g to 0.01 g/min·g.

In the exemplary embodiment, the rate at which the acidic silicic acid solution is added to the liquid can be calculated, using the following expression, as the rate of addition (S) of the acidic silicic acid solution (in terms of silica dry) per unit mass of silica dry contained in the solution in the reaction vessel.

$$( S ) = ( Rate of addition of acidic silicic acid solution per silica dry ) [ g / min ] / ( Mass of silica dry in solution in reaction vessel ) [ g ]$$

Here, for example, when the rate of addition of the acidic silicic acid solution per mass of silica dry changes in two stages, the mass of silica dry of the particles in the reaction vessel is calculated using the mass of silica dry in the reaction vessel at the completion of addition of each of the first addition and the second addition. When the rate of addition does not change, the calculation is performed using the mass of silica dry in the reaction vessel at the completion of Process A in Step 2a.

Herein, the rate of addition of the acidic silicic acid solution is calculated as described above in terms of the amount of the acidic silicic acid solution added (in terms of silica dry) per unit mass (unit area of seed particles) per unit time, regardless of whether the acidic silicic acid solution is added continuously or intermittently.

When the rate of addition [g/min] of the acidic silicic acid solution is changed one or more times and the n-th addition rate is set to Lₙ [g/min], a relationship of Lₙ₊₁<Lₙ is preferably satisfied. Here, n is a positive integer. That is, it is desirable to change the rate of addition of the acidic silicic acid solution during mixing one or more times and gradually decrease the rate of addition. In Step 2a, the acidic silicic acid solution is added to grow particles to a desired size, but in the invention, the reaction solution is continuously extracted, resulting in a decrease in the number of particles. Therefore, the acidic silicic acid solution may not deposit on the particle surfaces, and self-nucleation by silicic acid may occur. By slowing down the rate of addition of the acidic silicic acid solution from the second addition onwards, the occurrence of self-nucleation can be prevented and particles can be grown to have a desired size.

### Rate of Addition of Alkali

In Process A of Step 2a, in order to maintain the pH of the reaction solution, it is desirable to add the alkali continuously or intermittently to the solution mixture in parallel with the addition of the acidic silicic acid solution.

The rate of addition of alkali depends on the type and concentration of the alkali and cannot be uniformly limited, but it is desirable to add the alkali so that the pH of the reaction solution is in a range of 8.5 to 13.0.

SiO₂/A₂O Molar Ratio of Solution in Reaction Vessel

In Step 2a, the acidic silicic acid solution is added continuously or intermittently to the solution in the reaction vessel. However, the reaction solution (hereinafter also referred to as an “extracted solution”) is extracted continuously or intermittently, so that the pH of the reaction solution tends to decrease. A decrease in pH makes the added acidic silicic acid solution less soluble, and self-nucleation by silicic acid tends to occur more easily. Thus, in order to maintain the pH of the solution in the reaction vessel, it is desirable to adjust the pH by adding the alkali. In this case, the pH can be desirably adjusted by adding the alkali so that the SiO₂/A₂O molar ratio of the solution in the reaction vessel falls within a range from 20 to 160.

### pH of Solution in Reaction Vessel

As described above, there are no particular limitations on the type of alkali added to adjust the SiO₂/A₂O molar ratio of the solution in the reaction vessel to 20 or more and 160 or less, but examples thereof include sodium hydroxide, potassium hydroxide, lithium hydroxide, ammonia, and organic amines. The pH of the reaction solution adjusted by adding the alkali is preferably in a range of 8.5 to 13.0, more preferably in a range of 9.0 to 12.5. If the pH exceeds 13.0, the ionic strength in the reaction solution becomes too high. This causes the silica fine particles to aggregate and settle, or the particles to become irregularly shaped, making it difficult to obtain desired particles. If the pH is less than 8.5, the added acidic silicic acid solution becomes less soluble, and self-nucleation by silicic acid tends to occur easily.

### Process B

In Process B of Step 2a, the acidic silicic acid solution is continuously or intermittently added to the solution in the reaction vessel while the extracted solution is continuously extracted. In the early stage of extraction, the particle growth reaction has started but the seed particles have not yet grown sufficiently, so small-sized silica fine particles are extracted. In the later stage of extraction, the seed particles have grown sufficiently, so large-sized silica fine particles are extracted. By continuously extracting the extracted solution in this manner, silica fine particles with a wide particle size distribution can be obtained in the extracted solution.

It is desirable to mix the reaction solution remaining in the reaction vessel with the extracted solution. In Step 2a, the extraction is performed continuously, and preferably performed so that the solution mixture remains in the reaction vessel. The remaining solution mixture contains the largest particles that have grown the most. By mixing this solution mixture with the extracted solution, particles with a wider distribution can be obtained, and the components of the remaining reaction solution become the components of a peak on the large particle side of the silica fine particles according to the exemplary embodiment. Adjusting an extraction-rate ratio allows the distribution to have a peak also on a small particle side, or allows for the adjustment on the peak ratio between the small particle side and the large particle side. If the remaining solution mixture and the extracted solution are not mixed, the particle size distribution will have no peak on the large particle side. According to a trace experiment carried out by the inventors, it was found out that in a process in which the dispersion of seed particles and the acidic silicic acid solution are continuously added in a reaction vessel provided with an overflow line, such as the production method of Patent Literature 1, even if the extraction-rate ratio is adjusted, the particle size distribution with the peak on the large particle side as in the invention is not obtained.

### Extraction-Rate Ratio

The production method according to the exemplary embodiment is characterized in that the acidic silicic acid solution is added to the reaction solution to cause particle growth, while the reaction solution is extracted in order to broaden the particle size distribution.

When the rate of addition [g/min] (in terms of silica dry) of the acidic silicic acid solution in Process A of Step 2a is represented by X, and the rate of extraction [g/min] (in terms of silica dry) of the reaction solution (extracted solution) from the reaction vessel in Process B of Step 2a is represented by Z, the extraction-rate ratio (X/Z) defined by the following expression is preferably in a range of 0.2 to 3.0, more preferably in a range of 0.5 to 2.0, and particularly preferably in a range of 0.6 to 1.8.

$$Extraction - rate ratio ( X / Z ) = ( Silica dry [ g ] of acidic silicic acid solution per hour ) / ( Silica dry [ g ] of extracted solution per hour )$$

Generally, if the extraction-rate ratio is 1.0, the rate at which silica dry is added to the reaction vessel is the same as the rate at which silica dry is extracted. The amount of silica dry in the reaction vessel is thus constant. Although it depends on the concentration of the raw materials, the solution level in the reaction vessel is roughly constant under normal conditions. If the extraction-rate ratio exceeds 1.0, the extraction amount is small. The amount of silica dry in the reaction vessel thus increases, and the solution level in the reaction vessel normally rises gradually. If the extraction-rate ratio is less than 1.0, the amount of silica dry in the reaction vessel decreases, and the solution level in the reaction vessel normally falls gradually.

In the exemplary embodiment, if the extraction-rate ratio is less than 0.2, the rate of extraction is too fast, and the reaction vessel becomes empty or nearly empty in a short reaction time. Thus, the reaction has to be terminated and the particle size distribution does not become sufficiently broad. If the extraction-rate ratio exceeds 3.0, the rate of addition of the acidic silicic acid solution is too fast, which may lead to self-nucleation by the acidic silicic acid solution. Furthermore, the amount of silica dry in the reaction vessel gradually increases, and the solution level of the solution mixture normally rises. This may cause the overflow from the reaction vessel. Even if no overflow occurs, the size of the reaction vessel would need to be increased, which is not economical.

### Heat-Aging

In Step 2a, after performing Processes A and B, heat-aging is preferably performed on the remaining reaction solution. The aging temperature is preferably in a range of 40 degrees to 98 degrees C., and more preferably in a range of 60 degrees C. to 98 degrees C. The aging time is preferably in a range of 20 minutes to 120 minutes, and more preferably in a range of 30 minutes to 90 minutes. Such heat-aging can complete the reaction. If heat-aging is not performed, the added acidic silicic acid solution may remain without being deposited on particle surfaces, and the stability of the silica sol may be impaired.

When the acidic silicic acid solution is added in Step 2a, a base can be added as a pH adjuster, if necessary, to adjust the pH of the dispersion to the above range.

Exemplary bases that can be used include alkali metal hydroxides such as NaOH and KOH, metal carbonates such as potassium oxide, sodium carbonate, and ammonium carbonate, amines such as ammonia, monoethanolamine, and piperazine, and basic nitrogen compounds including quaternary ammonium hydroxides such as tetramethylammonium.

### Step 3a

In Step 3a, the reaction solution remaining in the reaction vessel at the completion of Step 2a is mixed with the reaction solution extracted in Process B of Step 2a to obtain the dispersion liquid of polishing silica fine particles.

In Process B of Step 2a, the extraction is performed continuously, and preferably performed so that the reaction solution remains in the reaction vessel. The reaction solution remaining in the reaction vessel contains the largest particles that have grown the most. Therefore, mixing this reaction solution with the extracted solution results in particles with a wider distribution. Mixing this reaction solution with the extracted solution causes the particle size distribution to have a peak on the large particle side. Adjusting the extraction-rate ratio allows the distribution to have a peak also on the small particle side, or allows for the adjustment on the peak ratio between the small particle side and the large particle side. If the reaction solution remaining in the reaction vessel and the extracted solution are not mixed, the particle size distribution will have no peak on the large particle side.

### Concentration Step

The dispersion liquid of polishing silica fine particles obtained by the first production method of the dispersion liquid of polishing silica fine particles according to the exemplary embodiment including Steps 1a to 3a may be concentrated to a desired concentration after the temperature is adjusted to within a range from room temperature to about 50 degrees C. The concentration may be performed using any means such as an ultrafiltration membrane or a rotary evaporator. Coarse particles may be removed by centrifugation or filtration using a filter, if desired.

### Second Production Method for Dispersion Liquid of Polishing Silica Fine Particles

A second production method for the dispersion liquid of polishing silica fine particles according to the exemplary embodiment will be described.

The dispersion liquid of polishing silica fine particles according to the exemplary embodiment described above can be preferably produced by the second production method for the dispersion liquid of polishing silica fine particles according to the exemplary embodiment.

The second production method for the dispersion according to the exemplary embodiment needs to include the following Steps 1b to 4b.

### Step 1b

In Step 1b, an acidic silicic acid solution and an alkali are introduced as raw materials into a reaction vessel that is kept unheated, and a solvent is added as necessary to prepare a first solution mixture. Herein, the first solution mixture is also referred to as “Step 1b solution”.

When these raw materials are introduced into the reaction vessel, splashing occurs on a bottom surface or inner wall of the reaction vessel or on the solution surface (the solution surfaces of the acidic silicic acid solution and the alkali introduced). If the raw materials are introduced into a heated reaction vessel, the splashed raw materials are likely to dry to become coarse aggregates, which may cause a problem. If the raw materials are introduced gradually enough to avoid splashing, the mixing time will be long and the economic efficiency will be poor.

When the dispersion of seed particles and the alkali are added to a heated reaction vessel as in the process described in Patent Literature 2, the dispersion of seed particles and the alkali are heated from the beginning of the addition, whereby the seed particles are likely to aggregate at an early stage.

The “unheated” means that no operation for increasing the temperature of the reaction vessel is performed. If the temperature of the unheated reaction vessel exceeds 40 degrees C. due to seasonal high temperatures or the like, it is recommended that the reaction vessel be cooled to have a temperature of less than 40 degrees C.

Preferably, the temperatures of the acidic silicic acid solution and the alkali at the stage of introducing them into the reaction vessel are both less than 40 degrees C.

### Acidic Silicic Acid Solution

As the acidic silicic acid solution, it is possible to use one obtained by dealkalizing an aqueous alkali silicate solution with a cation exchange resin. The concentration of the acidic silicic acid solution is, in terms of SiO₂, preferably in a range of 0.1% by mass to 10% by mass, more preferably in a range of 1% by mass to 7% by mass, and particularly preferably in a range of 2% by mass to 6% by mass. The pH of the acidic silicic acid solution is preferably in a range of 1 to 3.

The acidic silicic acid solution and the alkali are added so that the molar ratio of silica to alkali (in terms of oxide) in the first solution mixture is in a range of 1 to 10, and further a solvent is added as needed for adjustment so that the silica concentration in the first solution mixture is in a range of 0.1% by mass to 15% by mass.

Here, the molar ratio of silica to alkali (in terms of oxide) is represented by molar ratio=[moles of SiO₂]/[moles of A₂O], where A represents an alkali metal, ammonia, an organic alkali, an alkali metal in water glass, or the like. If the molar ratio of silica to alkali (in terms of oxide) is less than 1, the amount of alkali will be excessive, causing the ionic strength in the first solution mixture to be excessively high. This causes the silica fine particles produced in the subsequent Steps 2b and 3b to aggregate, makes it impossible to obtain particles with a true spherical shape, and makes it more likely that sedimentation will occur. Even if no sedimentation occurs, the increase in aggregates of silica fine particles makes it difficult to obtain monodispersed silica sol.

If the molar ratio of silica to alkali (in terms of oxide) exceeds 10, the amount of silica is so large that only small particles are obtained, making it difficult to obtain a desired size. In addition, since the alkali is relatively low, when the acidic silicic acid solution is added in the subsequent Step 2b, the pH of the reaction solution is significantly low. As a result, the added acidic silicic acid solution fails to deposit on the surfaces of silica fine particles, and self-nucleation occurs due to silicic acid, making it difficult to obtain silica sol with a desired particle size. The molar ratio of silica to alkali is preferably in a range of 2 to 8, and more preferably in a range of 2.5 to 6.

If the silica concentration in the first solution mixture is less than 0.1% by mass, it is easy to obtain monodispersed silica fine particles. However, because of a low silica concentration in the first solution mixture, production is not efficient and is uneconomical. If the silica concentration exceeds 15% by mass, the silica fine particles are likely to aggregate during mixing, making it difficult to obtain monodispersed silica fine particles. The silica concentration in the first solution mixture is more preferably in a range of 0.2% by mass to 10% by mass, and particularly preferably in a range of 0.3% by mass to 8% by mass.

When the molar ratio of silica to alkali (in terms of oxide) and the silica concentration in the first solution mixture are within the above-mentioned ranges, most of the silica fine particles avoid aggregation, but some of them aggregate and become irregularly-shaped particles. As a result, the silica fine particles in the dispersion liquid of silica fine particles according to the exemplary embodiment are mostly particles having a true spherical shape, but include irregularly-shaped particles in a range of 1.0% by number to 10% by number.

### Alkali

Examples of the alkali added in Step 1b include alkali silicates such as sodium silicate (water glass) and potassium silicate; alkali metals such as sodium hydroxide, potassium hydroxide, and lithium hydroxide; ammonia; and organic alkalis such as organic amines. Here, the alkali is typically added as an aqueous alkali solution. The alkali concentration of the aqueous alkali solution is not particularly limited, but is typically in a range of 1% by mass to 50% by mass.

### Solvent

Exemplary solvents that may be added in Step 1b, if necessary, include water, ion-exchanged water, pure water, ultrapure water, a mixed solvent containing water and a water-soluble organic solvent, and a water-soluble organic solvent.

### Step 2b

In Step 2b, the solution mixture prepared in Step 1b is stirred uniformly, heated, and held at a constant temperature (in a range of 40 degrees C. to 98 degrees C.) for a certain period of time. Subsequently, while maintaining the same temperature range, the acidic silicic acid solution is added continuously or intermittently to produce silica fine particles, obtaining a second solution mixture. Herein, the second solution mixture obtained in Step 2b is also referred to as “Step 2b solution”.

### Retention Temperature and Retention Time

In Step 2b, the first solution mixture prepared in Step 1b is heated to a temperature of 40 degrees C. or more and 98 degrees C. or less while stirring, and maintained in the same temperature range for a certain period of time. Here, the retention time is preferably in a range of 10 minutes to 120 minutes, and more preferably in a range of 20 minutes to 90 minutes. Maintaining this temperature allows the solution mixture to be sufficiently homogenized. If the retention time is less than 10 minutes, homogenization will be insufficient. Thus, the generation and growth of silica fine particles by the subsequent addition of acidic silicic acid solution will tend to be non-uniform. If the retention time exceeds 120 minutes, the homogenization of the solution mixture does not progress further. Instead, such a long retention time reduces production efficiency and economic efficiency.

Next, the acidic silicic acid solution is added while the temperature of this solution mixture is maintained in a range of 40 degrees C. to 98 degrees C. to produce silica fine particles. More specifically, in the initial stage of adding the acidic silicic acid solution, nuclear particles (polymers of silicic acid) are produced first, and these nuclear particles continue to grow in the acidic silicic acid solution added, thereby producing silica fine particles.

The addition time of the acidic silicic acid solution is preferably in a range of 3 hours to 48 hours. If the addition time is less than 3 hours, the rate of addition of the acidic silicic acid solution is too fast, which may lead to self-nucleation by the acidic silicic acid solution in addition to the production of desired silica fine particles. If the addition time exceeds 48 hours, the acidic silicic acid solution will not self-nucleate, but the mixing time will be too long, making it less economical. The particle size distribution of the silica fine particles produced in Step 2b shows a normal distribution and is a relatively sharp particle size distribution.

With regard to the amount (total amount) of the acidic silicic acid solution added in Step 2b, when the molar ratio of SiO₂ contained in the second solution mixture is represented by M2S and the molar ratio of alkali A in terms of oxide (i.e., in terms of A₂O) contained in the second solution mixture is represented by M2A, a value of M2S/M2A is preferably in a range of 20 to 160.

If the value of M2S/M2A is less than 20, the growth of the silica fine particles in the dispersion liquid of silica fine particles obtained by the production method according to the exemplary embodiment will be slow to make the size of the silica fine particles small, resulting in an insufficient polishing rate even when used as an abrasive. If the value of M2S/M2A exceeds 160, the particle size of the silica fine particles in the dispersion liquid of silica fine particles obtained by the production method according to the exemplary embodiment becomes excessively large. When this dispersion liquid of silica fine particles is used as an abrasive, at least scratches on a polishing-target substrate may occur significantly, which is undesirable. Furthermore, if the value of M2S/M2A exceeds 160, the mixing time becomes extremely long, which reduces the economic efficiency. The value of M2S/M2A is more preferably in a range of 40 to 140, still more preferably in a range of 50 to 130, and particularly preferably in a range of 60 to 120.

### Step 3b

In Step 3b after Step 2b, Process A and Process B as below are performed in parallel.
Process A: A reaction solution is prepared by continuously or intermittently adding an acidic silicic acid solution and an alkali to the reaction vessel filled with the second solution mixture.
Process B: Some of the reaction solution is extracted from the reaction vessel continuously or intermittently.

In Step 3b, Process A and Process B are performed in parallel. In Process A, the reaction solution is prepared by adding the acidic silicic acid solution to the second solution mixture filled in the reaction vessel to grow the silica fine particles to a desired size (here, the addition of the alkali for the purpose of maintaining the pH of the reaction solution and the addition of the acidic silicic acid solution for the purpose of growing particles are performed in parallel). In Process B, some of the reaction solution is extracted from the reaction vessel.

Since the particle growth reaction immediately proceeds upon the addition of the acidic silicic acid solution in Step 3b, the second solution mixture (Step 2b solution) is also referred to as the “reaction solution” or “Step 3b solution” for convenience after the start of addition of the acidic silicic acid solution in Step 3b.

As described in detail below, in the subsequent Step 4b, the reaction solution remaining in the reaction vessel after Step 3b is aged at high temperature and then the reaction solution extracted in Process B is added and mixed, thereby obtaining the dispersion liquid of polishing silica fine particles according to the exemplary embodiment having a broader particle size distribution.

With regard to the amount of the acidic silicic acid solution added to the Step 3b solution in Step 3b, when the number of moles of the silica contained in the Step 3b solution is represented by M3S and the number of moles of the alkali in terms of oxide contained in the Step 3b solution is represented by M3A, a value of M3S/M3A is preferably in a range of 20 to 160.

If the value of M3S/M3A is less than 20, the growth of the silica fine particles in the dispersion liquid of silica fine particles obtained by the production method according to the exemplary embodiment will be slow. This makes the size of the silica fine particles small and has difficulty providing a broad distribution, resulting in an insufficient polishing rate of the dispersion liquid of silica fine particles used as an abrasive. If the value of M3S/M3A exceeds 160, the particle size of the silica fine particles in the dispersion liquid of silica fine particles obtained by the production method according to the exemplary embodiment becomes excessively large. When this dispersion liquid of silica fine particles is used as an abrasive, at least scratches on a polishing-target substrate may occur significantly, which is undesirable. Furthermore, if the value of M3S/M3A exceeds 160, the mixing time becomes extremely long, which reduces the economic efficiency.

The value of M3S/M3A is more preferably in a range of 40 to 140, still more preferably in a range of 50 to 130, and particularly preferably in a range of 60 to 120.

### Reaction Temperature

The temperature of the Step 3b solution when the acidic silicic acid solution is added thereto is preferably in a range of 40 degrees to 98 degrees. If the temperature of the Step 3b solution is less than 40 degrees C., the added acidic silicic acid solution will be difficult to dissolve and therefore will be difficult to deposit on the surfaces of the silica fine particles. This causes self-nucleation by silicic acid, making it impossible to obtain particles a with desired size. If the temperature of the Step 3b solution exceeds 98 degrees C., the added acidic silicic acid solution will dissolve sufficiently and the silica fine particles will grow. However, an excessively high temperature of the dispersion liquid of silica fine particles or the reaction solution can be problematic in terms of energy efficiency and safety. The temperature of the Step 3b solution when the acidic silicic acid solution is added thereto is preferably in a range of 50 degrees to 98 degrees.

### Rate of Addition of Acidic Silicic Acid Solution

In Process A of Step 3b of the exemplary embodiment, the rate of addition of the acidic silicic acid solution to the reaction vessel filled with the Step 3b solution is expressed as silica dry [g] in the acidic silicic acid solution added per minute per mass [g] of silica particles contained in the solution in the reaction vessel. Here, the unit of the rate at which the acidic silicic acid solution is added to the liquid is [g/min·g]. The term “solution” is a general term for the liquid that fills the reaction vessel for convenience. Once the addition of the acidic silicic acid solution begins in Process A, the dispersion liquid of silica fine particles filling the reaction vessel undergoes the particle growth reaction and becomes the reaction solution. The solution includes the dispersion liquid of silica fine particles or the reaction solution, and means the liquid in the reaction vessel. Herein, the silica component contained in the liquid is also referred to as “silica dry”.

The rate at which the acidic silicic acid solution is added to the liquid is preferably in a range of 0.0001 g/min·g to 0.05 g/min·g. If the rate is within the above range, the acidic silicic acid solution added for particle growth is dissolved by alkali in the Step 3b solution and deposited on the surfaces of the silica fine particles, thereby promoting the growth of the silica fine particles. If the rate at which the acidic silicic acid solution is added to the liquid is less than 0.0001 g/min·g, the mixing time becomes too long for practical use, reducing the practicality and economic efficiency. If the rate at which the acidic silicic acid solution is added to the liquid exceeds 0.05 g/min·g, self-nucleation may proceed without the silicic acid being deposited on the particle surfaces, which is undesirable.

The rate at which the acidic silicic acid solution is added to the liquid is more preferably in a range of 0.0005 g/min·g to 0.02 g/min·g, and particularly preferably in a range of 0.001 g/min·g to 0.01 g/min·g.

In Process A of Step 3b of the exemplary embodiment, the rate at which the acidic silicic acid solution is added to the liquid can be calculated, using the following expression, as the rate of addition(S) of the acidic silicic acid solution (in terms of silica dry) per unit mass of silica dry contained in the solution in the reaction vessel.

$$( S ) = ( Rate of addition per silica dry of acid silicic acid solution ) [ g / min ] / ( Mass of silica dry in solution in reaction vessel ) [ g ]$$

Here, for example, when the rate of addition of the acidic silicic acid solution per mass of silica dry changes in two stages, the mass of silica dry of the particles in the reaction vessel is calculated using the mass of silica dry in the reaction vessel at the completion of addition of each of the first addition and the second addition. When the rate of addition does not change, the calculation is performed using the mass of silica dry in the reaction vessel at the completion of Process A in Step 3b.

Herein, the rate of addition of the acidic silicic acid solution is calculated as described above in terms of the amount of acidic silicic acid solution added (in terms of silica dry) per unit mass (unit area of silica fine particles) per unit time, regardless of whether the acidic silicic acid solution is added continuously or intermittently.

When the rate of addition [g/min] of the acidic silicic acid solution is changed one or more times and the n-th addition rate is set to Lₙ [g/min], a relationship of Lₙ₊₁≤Lₙ is preferably satisfied. Here, n is a positive integer. That is, it is desirable to change the rate of addition of the acidic silicic acid solution during mixing one or more times and gradually decrease the rate of addition. In Step 3b, the acidic silicic acid solution is added to grow particles to a desired size, but in the invention, the reaction solution is continuously extracted, resulting in a decrease in the number of particles. Therefore, the acidic silicic acid solution may not deposit on the particle surfaces, and self-nucleation by silicic acid may occur. By slowing down the rate of addition of the acidic silicic acid solution from the second addition onwards, the occurrence of self-nucleation can be prevented and particles can be grown to have a desired size.

### Rate of Addition of Alkali

In Process A of Step 3b, in order to maintain the pH of the reaction solution, it is desirable to add the alkali continuously or intermittently to the Step 3b solution in parallel with the addition of the acidic silicic acid solution.

The rate of addition of alkali depends on the type and concentration of the alkali and cannot be uniformly limited, but it is desirable to add the alkali so that the pH of the reaction solution is in a range of 8.5 to 13.0. If the pH of the reaction solution exceeds 13.0, the ionic strength in the reaction solution becomes too high. This causes the silica fine particles to aggregate and settle, or the particles to become irregularly shaped, making it difficult to obtain desired particles. If the pH is less than 8.5, the added acidic silicic acid solution becomes less soluble, and self-nucleation by silicic acid tends to occur easily. The pH of the reaction solution is preferably in a range of 9.0 to 12.5.

SiO₂/A₂O Molar Ratio of Solution in Reaction Vessel

In Step 3b, the acidic silicic acid solution is added continuously or intermittently to the solution in the reaction vessel. However, the reaction solution is extracted continuously or intermittently, so that the pH of the reaction solution tends to decrease. A decrease in pH makes the added acidic silicic acid solution less soluble, and self-nucleation by silicic acid tends to occur more easily. Thus, in order to maintain the pH of the solution in the reaction vessel, it is desirable to adjust the pH by adding the alkali. In this case, the pH can be desirably adjusted by adding the alkali so that the SiO₂/A₂O molar ratio of the solution in the reaction vessel falls within a range from 20 to 160.

### pH of Solution in Reaction Vessel

As described above, there are no particular limitations on the type of alkali added to adjust the SiO₂/A₂O molar ratio of the solution in the reaction vessel to 20 or more and 160 or less, but examples thereof include sodium hydroxide, potassium hydroxide, lithium hydroxide, ammonia, and organic amines. The pH of the reaction solution adjusted by adding the alkali is preferably in a range of 8.5 to 13.0, more preferably in a range of 9.0 to 12.5. If the pH exceeds 13.0, the ionic strength in the reaction solution becomes too high. This causes the silica fine particles to aggregate and settle, or the particles to become irregularly shaped, making it difficult to obtain desired particles. If the pH is less than 8.5, the added acidic silicic acid solution becomes less soluble, and self-nucleation by silicic acid tends to occur easily.

### Process B

In Process B of Step 3b, the reaction solution is produced while the acidic silicic acid solution is continuously or intermittently added to the solution in the reaction vessel, and some of the extracted solution is continuously extracted. Here, the reaction solution extracted is also referred to as the “extracted solution”.

In the early stage of extraction, the particle growth reaction has started but the silica fine particles have not yet grown sufficiently, so small-sized silica fine particles are extracted. In the later stage of extraction, the silica fine particles have grown sufficiently, so large-sized silica fine particles are extracted. By continuously extracting the extracted solution in this manner, silica fine particles with a wide particle size distribution can be obtained in the extracted solution.

It is desirable to mix the reaction solution remaining in the reaction vessel with the extracted solution. In Step 3b, the extraction is performed continuously, and preferably performed so that the solution mixture remains in the reaction vessel. The remaining solution mixture contains the largest particles that have grown the most. By mixing this solution mixture with the extracted solution, particles with a wider distribution can be obtained, and the components of the remaining reaction solution become the components of a peak on the large particle side of the silica fine particles according to the exemplary embodiment. Adjusting the extraction-rate ratio allows the distribution to have a peak also on the small particle side, or allows for the adjustment on the peak ratio between the small particle side and the large particle side. If the remaining solution mixture and the extracted solution are not mixed, the particle size distribution will have no peak on the large particle side. According to a trace experiment carried out by the inventors, it was found out that in a process in which the dispersion of seed particles and the acidic silicic acid solution are continuously added in a reaction vessel provided with an overflow line, such as the production method of Patent Literature 1, even if the extraction-rate ratio is adjusted, the particle size distribution with the peak on the large particle side as in the invention is not obtained.

### Extraction-Rate Ratio

The production method according to the exemplary embodiment is characterized in that the acidic silicic acid solution is added to the reaction solution to cause particle growth, while the reaction solution is extracted in order to broaden the particle size distribution.

When the rate of addition [g/min] (in terms of silica dry) of the acidic silicic acid solution in Process A of Step 3b is represented by X, and the rate of extraction [g/min] (in terms of silica dry) of the reaction solution (extracted solution) from the reaction vessel in Process B of Step 3b is represented by Z, the extraction-rate ratio (X/Z) defined by the following expression is preferably in a range of 0.2 to 3.0, more preferably in a range of 0.5 to 2.0, and particularly preferably in a range of 0.6 to 1.8.

$$Extraction - rate ratio ( X / Z ) = ( Silica dry [ g ] of acidic silicic acid solution per hour ) / ( Silica dry [ g ] of extracted solution per hour )$$

Generally, if the extraction-rate ratio is 1.0, the rate at which silica dry is added to the reaction vessel is the same as the rate at which silica dry is extracted. The amount of silica dry in the reaction vessel is thus constant. Although it depends on the concentration of the raw material, the solution level in the reaction vessel is roughly constant under normal conditions. If the extraction-rate ratio exceeds 1.0, the extraction amount is small. The amount of silica dry in the reaction vessel thus increases, and the solution level in the reaction vessel normally rises gradually. If the extraction-rate ratio is less than 1.0, the amount of silica dry in the reaction vessel decreases, and the solution level in the reaction vessel normally falls gradually.

In the exemplary embodiment, if the extraction-rate ratio is less than 0.2, the rate of extraction is too fast, and the reaction vessel becomes empty or nearly empty in a short reaction time. Thus, the reaction has to be terminated and the particle size distribution does not become sufficiently broad. If the extraction-rate ratio exceeds 3.0, the rate of addition of the acidic silicic acid solution is too fast, which may lead to self-nucleation by the acidic silicic acid solution. Furthermore, the amount of silica dry in the reaction vessel gradually increases, and the solution level of the solution mixture normally rises. This may cause the overflow from the reaction vessel. Even if no overflow occurs, the size of the reaction vessel would need to be increased, which is not economical.

When the acidic silicic acid solution is added in Step 3b, a base can be added as a pH adjuster, if necessary, to adjust the pH of the dispersion to the above range.

Exemplary bases that can be used include alkali metal hydroxides such as NaOH and KOH, metal carbonates such as potassium oxide, sodium carbonate, and ammonium carbonate, amines such as ammonia, monoethanolamine, and piperazine, and basic nitrogen compounds including quaternary ammonium hydroxides such as tetramethylammonium.

### Step 4b

In Step 4b, the reaction solution remaining in the reaction vessel at the completion of Step 3b is subjected to heat-aging, and then mixed with the reaction solution extracted in Process B of Step 3b to obtain the dispersion liquid of polishing silica fine particles.

### Heat-Aging

It is necessary to perform heat-aging on the remaining reaction solution. The aging temperature needs to be in a range of 40 degrees to 98 degrees C., and more preferably in a range of 60 degrees C. to 98 degrees C. The aging time needs to be in a range of 20 minutes to 120 minutes, and more preferably in a range of 30 minutes to 90 minutes. Such heat-aging can complete the reaction. If heat-aging is not performed, the added acidic silicic acid solution may remain without being deposited on particle surfaces, and the stability of the silica sol may be impaired.

### Mixing Process

In Process B of Step 3b, the extraction is performed continuously as described above, but needs to be performed so that the reaction solution remains in the reaction vessel. The reaction solution remaining in the reaction vessel contains the largest particles that have grown the most. Mixing this reaction solution with the extracted solution results in particles with a wider distribution. Mixing this reaction solution with the extracted solution causes the particle size distribution to have a peak on the large particle side. Adjusting the extraction-rate ratio allows the distribution to have a peak also on the small particle side, or allows for the adjustment on the peak ratio between the small particle side and the large particle side. If the reaction solution remaining in the reaction vessel and the extracted solution are not mixed, the particle size distribution will have no peak on the large particle side.

### Concentration Step

The dispersion liquid of polishing silica fine particles obtained by the second production method of the dispersion liquid of polishing silica fine particles according to the exemplary embodiment including Steps 1b to 4b may be concentrated to a desired concentration after the temperature is adjusted to within a range from room temperature to about 50 degrees C. The concentration may be performed using any means such as an ultrafiltration membrane or a rotary evaporator. Coarse particles may be removed by centrifugation or filtration using a filter, if desired.

### EXAMPLES

The invention will be described in more detail below with reference to Examples, but the invention is not limited to the Examples. In addition, the methods for measuring various properties of the silica fine particles or the dispersion liquid of silica fine particles in Examples and Comparatives were as follows, unless otherwise specified.

(1) Particle Size in terms of Specific Surface Area

The particle size in terms of specific surface area can be calculated by measuring a specific surface area Sa of silica fine particles and using the following expression. (De)(nm)=6000/(ρ×Sa)

Here, ρ represents a density of the silica fine particles, 2.2 [g/cm³].

When the specific surface area of silica fine particles is 100 m²/g or more, sintering progresses during firing in the BET method, so the specific surface area (SA) was obtained by the titration method and the particle size in terms of specific surface area (De) was calculated from the expression (De)=6000/(SA×ρ).

### BET Method

Adjustment was performed on 50 mL of the dispersion liquid of silica fine particles (silica concentration: 40% by mass) with HNO₃ to a pH of 3.5, to which 40 mL of 1-propanol was added. Then, the solution was dried at 110 degrees C. for 16 hours to obtain a sample. The sample was pulverized in a mortar and thereafter burned in a muffle furnace at 500 degrees C. for one hour to obtain a measurement sample. Then, a specific surface area meter (model number: Multisorb 12 produced by Yuasa Ionics Co., Ltd.) was used to calculate the specific surface area from the amount of adsorbed nitrogen by the single-point BET process according to the nitrogen adsorption method (BET method).

Specifically, 0.5 g of the sample was placed in a measurement cell and subjected to degassing treatment at 300 degrees C. for 20 minutes under flow of a mixed gas of 30 volume % of nitrogen and 70 volume % of helium, then kept under flow of the mixed gas at the liquid nitrogen temperature, so as to allow the sample to adsorb nitrogen under an equilibrium condition. Next, the temperature of the sample was gradually elevated to room temperature under a continuous flow of the mixed gas, the amount of released nitrogen during this process was detected, and the specific surface area of the silica fine particles was determined from a previously prepared calibration curve.

### Titration Method

First, a sample corresponding to 1.5 g of SiO₂ was collected in a beaker and placed in a thermostatic reactor (25 degrees C.) and pure water was added to make the liquid volume 90 mL. The following operation was performed in the thermostatic reactor kept at 25 degrees C.

Next, a 0.1 mol/L aqueous hydrochloric acid solution was added thereto to adjust the pH to 3.6. Furthermore, 30 g of sodium chloride was added and the mixture was diluted with pure water to 150 mL, and stirred for 10 minutes.

Then, a pH electrode was set and a 0.1 mol/L sodium hydroxide solution was added dropwise with stirring to adjust the pH to 4.0. The sample adjusted to a pH of 4.0 was titrated with the 0.1 mol/L sodium hydroxide solution, the titer and the pH value were recorded at 4 or more points in a pH range of 8.7 to 9.3, and a calibration curve was prepared by setting the titer of the 0.1 mol/L sodium hydroxide solution as X and the pH value at the time of titration as Y.

The consumed amount V (mL) of the 0.1 mol/L sodium hydroxide solution required for 1.5 g of SiO₂ at a pH of 4.0 to 9.0 was determined from the expression V=(A×f×100×1.5)/(W×C), and this was used to determine the specific surface area according to the expression SA=29.0V−28.

In the above expression, A represents the titer (mL) of the 0.1 mol/L sodium hydroxide solution required for 1.5 g of SiO₂ at a pH of 4.0 to 9.0, f represents the titer of the 0.1 mol/L sodium hydroxide solution, C represents the SiO₂ concentration (%) in the sample, and W represents the amount (g) of the collected sample.

### (2) Measurement of Particle Size Distribution in Terms of Weight, Weight Average Particle Size (D₅₀), and the Like of Group of Particles

The silica particle dispersion was diluted with a 0.05 mass % aqueous solution of sodium dodecyl sulfate to a solid content concentration of 2 mass %. Then, 0.1 mL of this was injected with a syringe into a known disk centrifugal particle size distribution measuring device (manufactured by CPS Instruments) and measured at 18,000 rpm in a density gradient solution of 8% to 24% sucrose to determine the particle size distribution in terms of weight.

From the measurement results of particle size distribution in terms of weight, there were calculated a 10% cumulative particle size (D₁₀), a 90% cumulative particle size (D₉₀), and a 50% cumulative particle size (D₅₀), cumulated from a smaller particle size side.

### (3) Average Sphericity and Irregularly-Shaped Particle Proportion of Group of Particles Measured by Image Analysis

In an image or photograph including 200 or more silica fine particles in the dispersion liquid of silica fine particles within the same field of view, short and long diameters of 200 randomly selected silica fine particles were measured by a scanning electron microscope (magnification 200,000 times). Then, the ratio of the short diameter to the long diameter of each particle was calculated for a randomly selected field of view, and the particle size distribution of the group of particles was created. Herein, an ultra-high resolution field emission scanning electron microscope S-5500 (manufactured by Hitachi High-Tech Corporation) was used as the scanning electron microscope.

The specific method for measuring silica fine particles was to take the maximum diameter of the silica fine particle in the projected image as a long axis, measure the length of the long axis, and take the measured value as the long diameter. In addition, a point was determined on the long axis that divided the long axis into two equal parts, and two points were found where a straight line orthogonal to the above point intersected with the particle contour of the silica fine particle image. A distance between these two points was measured as the short diameter, and the degree of shape irregularity (short diameter/long diameter value) was calculated.

From the particle size distribution of the group of particles, the average sphericity and the irregularly-shaped particle proportion (number of irregularly-shaped particles/total number of particles×100) of the group of particles were calculated.

### (4) Coefficient of Variation of Particle Size Distribution Area

A dispersion liquid of silica fine particles with a silica concentration of 1% by mass was prepared, and the particle size distribution in terms of weight of the group of particles was first determined using a disk centrifugal particle size distribution measuring device (manufactured by CPS Instruments).

In the particle size distribution in terms of weight of the group of particles, the particle size range from the 1% cumulative particle size (D₁) to the 99% cumulative particle size (D₉₉), cumulated from the smaller particle size side, was divided into six equal particle size ranges, which were designated S1, S2, S3, S4, S5, and S6. The coefficient of variation (CV value) of the particle size distribution area corresponding to each particle size range was calculated.

### (5) Polishing Test Method <Polishing SiO₂ Film>

The dispersion of polishing abrasive grains obtained in each of Examples and Comparatives was adjusted to have a solid content concentration of 1.0% by mass and a pH of 6.0 by adding nitric acid.

Next, as polishing-target substrates, a substrate having a SiO₂ insulating film (2 μm thick) produced by a deposition method and a substrate having a thermally oxidized film (2 μm thick) made of SiO₂ produced by a thermal oxidation method were prepared.

Each of the polishing-target substrates was set on a polishing device (NF300 manufactured by Nanofactor Co., Ltd.), and polished using a polishing pad (“IC-1000/SUBA400 Concentric Type” manufactured by Nitta Haas Inc.) at a substrate load of 0.08 Mpa, a table rotating speed of 87 rpm, and a polishing head rotation speed of 93 rpm while feeding the dispersion of polishing abrasive grains at a rate of 20 mL/min for 15 minutes.

The change in weight of each of the substrates before and after polishing was then determined, and the polishing rate was calculated.

### Polishing Aluminum Hard Disk

The dispersion of polishing abrasive grains obtained in each of Examples and Comparatives was adjusted to have a solid content concentration of 9% by mass and a pH of 2.0 by adding nitric acid.

An aluminum hard disk substrate was set on a polishing device (NF300 manufactured by Nanofactor Co., Ltd.), and polished using a polishing pad (“Polytex (12” manufactured by Nitta Haas Inc.) at a substrate load of 0.05 Mpa, a table rotating speed of 30 rpm, and a polishing head rotation speed of 60 rpm while feeding the dispersion of polishing abrasive grains at a rate of 20 mL/min for 10 minutes. The entire surface was observed using an ultrafine defect visualizing macro inspection system (product name: Maicro-Max produced by Vision Psytec) at Zoom 15, and the number of scratches (linear scratches) found on the polished substrate surface corresponding to an area of 65.97 cm² was counted up.

### (6) Measurement of Mass Ratio of Polyethyleneimine to Silica at Equivalence Point

In streaming potential measurement (using cationic polymeric polyethyleneimine having a weight average molecular weight of 600 as a titration reagent), the mass ratio of polyethyleneimine to silica at an equivalence point was measured.

Specifically, for the dispersion liquid of polishing silica fine particles obtained, a ratio (V/SiO₂) of an amount (V [g]) of addition of a cationic solid content (cationic polymeric polyethyleneimine having a weight average molecular weight of 600) in a cation titrant at a knick to a SiO₂ solid content [g] was measured.

The cation titration was performed as follows to determine V/SiO₂.

The cation titration was performed by dropping 0.08 mass % of polyethyleneimine (molecular weight 600) as a cation titrant into 80 g of a silica particle dispersion whose solid content concentration had been adjusted to 0.5 mass %.

A streaming potential curve was obtained by plotting, on a graph, a relationship between the amount of the consumption of the cation titrant (mL) and the streaming potential of the dispersion (mV). The amount of consumption of the cation titrant was scaled on the X-axis, and the streaming potential of the dispersion was scaled on the Y-axis.

On the streaming potential curve, a point (inflection point) where the streaming potential abruptly changes relative to the amount of consumption of the cation titrant is taken as a knick. The amount of addition of cationic solid content (V, g) was determined from the amount of consumption of a cation colloidal titrant at the knick.

V/SiO₂ was determined from those results.
V: Amount of addition of cationic solid content (g) in the cation titrant at the knick
SiO₂: Silica fine particle solid content subjected to titration (g)

### Preparation of Acidic Silicic Acid Solution

Pure water was added to an aqueous sodium silicate solution (silica concentration: 24.06% by mass, Na₂O concentration: 7.97% by mass) to obtain an aqueous sodium silicate solution (silica concentration: 5% by mass). Eighteen kilograms of the thus obtained aqueous sodium silicate solution was allowed to pass through 6 L of strongly acidic cation exchange resin (SK1BH manufactured by Mitsubishi Chemical Corporation) at a space velocity of 3.0 h⁻¹, to obtain 18 kg (silica concentration: 4.5% by mass, pH: 2.7). In the following Examples and Comparatives, this acidic silicic acid solution or an acidic silicic acid solution equivalent to this acidic silicic acid solution was appropriately concentrated or diluted and used as a raw material.

### Example 1-1

Into an unheated mixing vessel (reaction vessel, internal volume 10 L), 4,527 g of pure water at 25 degrees C. was added, and 413.6 g of a dispersion liquid of silica fine particles (Cataloid SI-50 manufactured by JGC Catalysts and Chemicals Ltd., SiO₂ concentration: 48.35% by mass, Na₂O concentration: 0.49% by mass, particle size in terms of specific surface area: 26.2 nm, liquid temperature: 25 degrees C.) was further added to obtain a diluted dispersion liquid of silica fine particles.

An aqueous potassium hydroxide solution (Super Kali R manufactured by TOAGOSEI CO., LTD., KOH concentration: 48.7% by mass) was diluted with pure water to a KOH concentration of 4.8% by mass. 20.83 g of this diluted solution was added to the diluted dispersion liquid of silica fine particles and stirred until homogenized. After stirring, the temperature was raised to 95 degrees C. and maintained for 30 minutes. Next, 14.198 kg of an acidic silicic acid solution (SiO₂ concentration: 4.45% by mass) and 1.475 kg of an aqueous potassium hydroxide solution (KOH concentration: 1.0% by mass) were each added for 18 hours.

Here, the rate of addition of the acidic silicic acid solution (SiO₂ concentration: 4.45% by mass, pH: 2.7) was 14.40 g/min from the start of addition until the elapse of 9 hours, and 11.90 g/min from the elapse of 9 hours until the elapse of 18 hours.

Furthermore, the rate of addition of the aqueous potassium hydroxide solution (KOH concentration: 1.0% by mass) was 1.54 g/min from the start of addition until the elapse of 9 hours, and was 1.19 g/min from the elapse of 9 hours until the elapse of 18 hours.

In parallel with the addition of the acidic silicic acid solution and the aqueous potassium hydroxide solution, 15.04 kg of the reaction solution (part of the reaction solution, hereinafter also referred to as the “extracted solution”) was extracted from the mixing vessel. Here, the rate of extraction of the extracted solution was 15.93 g/min from the start of extraction until the elapse of 9 hours, and 11.92 g/min from the elapse of 9 hours until the elapse of 18 hours.

After the addition of the acidic silicic acid solution and the aqueous potassium hydroxide solution and the extraction of the extracted solution, 5.59 kg of the reaction solution remained in the mixing vessel. This solution was kept at 95 degrees C. for 1 hour and then cooled to room temperature.

The ratio of silica dry in the acidic silicic acid solution to silica dry in the extracted solution (silica dry in acidic silicic acid solution/silica dry in extracted solution) during reaction is shown in Table 1. Herein, the silica solid content (mass) is also referred to as “silica dry”.

The reaction solution remaining in the mixing vessel and the extracted solution were mixed until homogenized. The resulting mixture had a pH of 10.2, a particle size in terms of specific surface area of 45.5 nm, and a SiO₂ concentration of 4.03% by mass. This mixture was concentrated using an ultrafiltration membrane SIP-1013 manufactured by Asahi Kasei Corporation until the SiO₂ concentration reached 12.0% by mass, to obtain a dispersion liquid of polishing silica fine particles.

The dispersion liquid of polishing silica fine particles obtained was evaluated in various aspects by the above-mentioned methods. Table 2 shows the evaluation results.

The conditions for preparing the dispersion liquid of polishing silica fine particles in Example 1 are shown in Table 1.

### Examples 1-2 and 1-3

A dispersion liquid of polishing silica fine particles was obtained in the same manner as in Example 1-1, except that the preparation conditions were changed as shown in Table 1.

Then, the dispersion liquid of polishing silica fine particles obtained was evaluated similarly to Example 1-1. Table 2 shows the obtained results.

### Comparative 1-1

Into a mixing vessel of a 10 L internal volume, 4,522 g of pure water at 95 degrees C. was added, and 461.2 g of a dispersion liquid of silica fine particles (Cataloid SI-50 manufactured by JGC Catalysts and Chemicals Ltd., SiO₂ concentration: 48.35% by mass, Na₂O concentration: 0.49% by mass, particle size in terms of specific surface area: 26.2 nm, liquid temperature: 25 degrees C.) was further added. To this, 16.56 g of a solution obtained by diluting 48.6 mass % of NaOH (sodium hydroxide manufactured by JGC Catalysts and Chemicals Ltd.) with pure water to 4.8 mass % of NaOH concentration was added, and the mixture was stirred until homogenized and then maintained for 30 minutes.

Then, 3.519 kg of a solution obtained by diluting 21.520 kg of an acidic silicic acid solution with a SiO₂ concentration of 4.55% by mass, 7.121 kg of a 0.25 mass % NaOH aqueous solution, and a dispersion liquid of silica fine particles (Cataloid SI-50, manufactured by JGC Catalysts and Chemicals Ltd.) with pure water to a SiO₂ concentration of 12%, was added for 48 hours. At this time, the rate of addition of the acidic silicic acid solution was 7.47 g/min, the rate of addition of the 0.25 mass % NaOH aqueous solution was 2.47 g/min, and the rate of addition of the dispersion liquid of silica fine particles was 1.22 g/min. Furthermore, in parallel with the addition, 32.47 kg of the solution mixture was extracted from the mixing vessel. At this time, the rate of extraction was 11.27 g/min. After the addition and extraction were completed, 4.49 kg of the solution mixture remained in the mixing vessel, and this solution was cooled to room temperature. The ratio of silica dry in the acidic silicic acid solution to silica dry in the extracted solution (silica dry in acidic silicic acid solution/silica dry in extracted solution) during mixing was 0.69.

The reaction solution remaining in the mixing vessel and the reaction solution extracted were mixed until homogenized. The resulting mixture had a pH of 10.3, a particle size in terms of specific surface area of 33.3 nm, and a SiO₂ concentration of 4.36% by mass. This mixture was concentrated using an ultrafiltration membrane SIP-1013 manufactured by Asahi Kasei Corporation until the SiO₂ concentration reached 12.0% by mass, to obtain a dispersion liquid of silica fine particles.

The dispersion liquid of silica fine particles obtained was evaluated similarly to Example 1. Table 2 shows the results.

The conditions for preparing the dispersion liquid of silica fine particles in Comparative 1-1 are shown in Table 1.

### Comparative 1-2

Cataloid SI-45P (dispersion liquid of silica fine particles) manufactured by JGC Catalysts and Chemicals Ltd. was evaluated similarly to Example 1. Table 2 shows the obtained results.

TABLE 1

| | | | Ex. | Ex. | Ex. | Comp. |
|---|---|---|---|---|---|---|
| | | Unit | 1-1 | 1-2 | 1-3 | 1-1 |
| Step | Pure water (amount added) | g | 4,527 | 4,477 | 2,939 | 4,522 |
| 1 | Dispersion liquid of silica fine particles (amount added) | g | 413.6 | 413.6 | 206.8 | 461.2 |
| | SiO₂ concentration | % by mass | 48.35 | 48.35 | 48.35 | 48.35 |
| | Na₂O concentration | % by mass | 0.49 | 0.49 | 0.49 | 0.49 |
| | Particle size in terms of specific surface area | nm | 26.2 | 26.2 | 26.2 | 26.2 |
| | Aqueous solution of alkali hydroxide (amount added) | g | 20.83 | 20.83 | 10.42 | 16.56 |
| | Concentration of alkali hydroxide | % by mass | 4.8 | 4.8 | 4.8 | 4.8 |
| Step | Retention temperature | ° C. | 95 | 95 | 95 | 95 |
| 2 | Retention time | min | 30 | 30 | 30 | 30 |
| | Acidic silicic acid solution (total amount added) | kg | 14.198 | 14.040 | 6.975 | 21.520 |
| | SiO₂ concentration | % by mass | 4.45 | 4.50 | 4.50 | 4.55 |
| | Time required for addition | hrs. | 18 | 18 | 18 | 48 |
| | Rate of addition (from start until elapse of 5 hours) | g/min | 14.40 | 14.87 | 8.91 | 7.47 |
| | Rate of addition (from elapse of 5 hours until elapse of 9 hours) | g/min | 14.40 | 14.87 | 7.03 | 7.47 |
| | Rate of addition (from elapse of 9 hours until elapse of 18 hours) | g/min | 11.90 | 11.13 | 4.84 | 7.47 |
| | Rate of addition (from elapse of 18 hours until elapse of 48 hours) | g/min | | | | 7.47 |
| | Aqueous solution of alkali hydroxide (total amount added) | kg | 1.475 | 1.475 | 2.901 | 7.121 |
| | Concentration of alkali hydroxide | % by mass | 1 | 1 | 0.25 | 0.25 |
| | Time required for addition | hrs. | 18 | 18 | 18 | 48 |
| | Rate of addition (from start until elapse of 5 hours) | g/min | 1.54 | 1.56 | 3.70 | 2.47 |
| | Rate of addition (from elapse of 5 hours until elapse of 9 hours) | g/min | 1.54 | 1.56 | 2.93 | 2.47 |
| | Rate of addition (from elapse of 9 hours until elapse of 18 hours) | g/min | 1.19 | 1.18 | 2.02 | 2.47 |
| | Rate of addition (from elapse of 18 hours until elapse of 48 hours) | g/min | | | | 2.47 |
| | Dispersion liquid of silica fine particles (total amount added) | kg | | | | 3.519 |
| | SiO₂ concentration | % by mass | | | | 12.00 |
| | Na₂O concentration | % by mass | | | | 0.12 |
| | Particle Size in terms of specific surface area | nm | | | | 26.2 |
| | Time required for addition | hrs. | | | | 48 |
| | Rate of addition (from start until elapse of 5 hours) | g/min | | | | 1.22 |
| | Rate of addition (from elapse of 5 hours until elapse of 9 hours) | g/min | | | | 1.22 |
| | Rate of addition (from elapse of 9 hours until elapse of 18 hours) | g/min | | | | 1.22 |
| | Rate of addition (from elapse of 18 hours until elapse of 48 hours) | g/min | | | | 1.22 |
| | Extracted solution (total amount extracted) | kg | 15.04 | 18.62 | 9.92 | 32.47 |
| | Time required for extraction | hrs. | 18 | 18 | 18 | 48 |
| | Rate of extraction (from start until elapse of 5 hours) | g/min | 15.93 | 19.69 | 12.70 | 11.27 |
| | Rate of extraction (from elapse of 5 hours until elapse of 9 hours) | g/min | 15.93 | 19.69 | 9.99 | 11.27 |
| | Rate of extraction (from elapse of 9 hours until elapse of 18 hours) | g/min | 11.92 | 14.80 | 6.87 | 11.27 |
| | Rate of extraction (from elapse of 18 hours until elapse of 48 hours) | g/min | | | | 11.27 |
| | Rate at which silica dry in acidic silicic acid solution is added to | g/min · g | 0.0032 | 0.0049 | 0.0040 | 0.0016 |
| | silica dry (at completion of first addition) | | | | | |
| | Rate at which silica dry in acidic silicic acid solution is added to | g/min · g | 0.0023 | 0.0061 | 0.0032 | |
| | silica dry (at completion of second addition) | | | | | |
| | Rate at which silica dry in acidic silicic acid solution is added to | g/min · g | | | 0.0022 | |
| | silica dry (at completion of third addition) | | | | | |
| | Reaction solution remaining in reaction vessel at completion of step 2 | kg | 5.59 | 1.54 | 2.85 | 4.49 |
| | (residual amount) | | | | | |
| | Silica dry in acidic silicic acid solution (X)/Silica dry in extracted | — | — | — | — | — |
| | solution (Z) | | | | | |
| | X/Z value (from start until elapse of 5 hours) | — | 1.00 | 0.83 | 1.00 | 0.69 |
| | X/Z value (from elapse of 5 hours until elapse of 9 hours) | — | 1.00 | 0.83 | 1.00 | 0.69 |
| | X/Z value (from elapse of 9 hours until elapse of 18 hours) | — | 1.10 | 0.83 | 1.00 | 0.69 |
| | X/Z value (from elapse of 18 hours until elapse of 48 hours) | — | | | | 0.69 |
| | Aging temperature | ° C. | 95 | 95 | 95 | — |
| | Aging time | Hrs. | 1 | 1 | 1 | — |

TABLE 2

| | | Ex. | Ex. | Ex. | Comp. | Comp. |
|---|---|---|---|---|---|---|
| | Unit | 1-1 | 1-2 | 1-3 | 1-1 | 1-2 |
| Particle size in terms of specific surface area of group of particles | nm | 45.5 | 43.3 | 44.7 | 33.3 | 42.6 |
| Average sphericity of group of particles (image analysis) | — | 0.92 | 0.92 | 0.92 | 0.90 | 0.91 |
| Particle size distribution in terms of weight | nm | 39 | 36 | 38 | 33 | 52 |
| 10% cumulative particle size (D10) | | | | | | |
| Particle size distribution in terms of weight | nm | 68 | 62 | 66 | 48 | 58 |
| 50% cumulative particle size (D50) | | | | | | |
| Particle size distribution in terms of weight | nm | 95 | 130 | 104 | 79 | 70 |
| 90% cumulative particle size (D90) | | | | | | |
| Particle size distribution in terms of weight | — | 0.82 | 1.51 | 1.00 | 0.97 | 0.30 |
| (D90 − D10)/D50 | | | | | | |
| Particle size distribution in terms of weight | Yes or No | Yes | Yes | Yes | No | No |
| Distribution peak on large particle size side | | | | | | |
| Particle size distribution in terms of weight | nm | 89 | 85 | 82 | 27 | 37 |
| Peak position (particle size) on large particle size side | | | | | | |
| Irregularly-shaped particle proportion (image analysis) | % by number | 2.6 | 3.3 | 2.2 | 1.2 | 1.7 |
| Particle size distribution obtained from particle size/number | % | 35.2 | 60.7 | 26.6 | 70.7 | 81.2 |
| of particles CV value of particle size distribution area | | | | | | |
| PEI/SiO₂ dry ratio at equivalence point in streaming potential | — | 1.5 | 1.4 | 1.6 | 1.3 | 1.7 |
| measurement | | | | | | |
| Silica dry concentration in dispersion liquid of silica fine particles | % by mass | 12.0 | 12.0 | 12.0 | 12.0 | 40.5 |
| Polishing rate (SiO₂ film) | nm/min | 17 | 16 | 15 | 7 | 10 |
| Polishing rate (Aluminum hard disk) | nm/min | 66 | 71 | 67 | 64 | 38 |
| Scratches (Aluminum hard disk) | number | 15 | 11 | 22 | 46 | 13 |

### Example 2-1

In a mixing vessel with an internal volume of 10 L, 304.66 g of pure water was added, and 6.72 g of an aqueous potassium hydroxide solution (KOH with a KOH concentration of 48.7% by mass, Super Kali R manufactured by TOAGOSEI CO., LTD.) was further added. To this, 160.88 g of an acidic silicic acid solution (SiO₂ concentration of 4.55% by mass) was added and stirred until homogenized. After stirring, the temperature was raised to 98 degrees C. and maintained for 30 minutes.

Then, 2.918 kg of an acidic silicic acid solution (SiO₂ concentration: 4.55% by mass) was added for 11 hours. At this time, the rate of addition of the acidic silicic acid solution was 4.42 g/min. After the addition was completed, 351.27 g of pure water was added to maintain the temperature at 98 degrees C. Next, 14.338 kg of an acidic silicic acid solution (SiO₂ concentration: 4.55% by mass) and 3.046 kg of an aqueous potassium hydroxide solution (KOH concentration: 0.5% by mass) were added for 24 hours. Furthermore, in parallel with the addition of the acidic silicic acid solution and the aqueous potassium hydroxide solution, a total of 17.24 kg of the reaction solution was extracted from the mixing vessel. The rate of addition of the acidic silicic acid solution, the rate of addition of 0.5 mass % aqueous potassium hydroxide solution, and the rate of extraction, for each elapsed time range are shown in Table 3. Table 3 also shows the rate at which the silica dry in acidic silicic acid solution is added to the silica dry for each elapsed time range. After the addition and extraction are completed, 3.50 kg of the reaction solution remained in the mixing vessel, and this solution was kept at 98 degrees C. for 1 hour and then cooled to room temperature.

The ratio of silica dry in the acidic silicic acid solution to silica dry in the extracted solution for each elapsed time range during mixing (silica dry in acidic silicic acid solution/silica dry in extracted solution) is shown in Table 3.

The reaction solution remaining in the mixing vessel and the reaction solution extracted were mixed until homogenized. The resulting mixture had a pH of 10.1, a particle size in terms of specific surface area of 36.9 nm, and a SiO₂ concentration of 3.75% by mass. This mixture was concentrated using an ultrafiltration membrane SIP-1013 manufactured by Asahi Kasei Corporation until the SiO₂ concentration reached 12.0 concentration %, to obtain a dispersion liquid of polishing silica fine particles.

The dispersion liquid of polishing silica fine particles obtained was evaluated in various aspects by the above-mentioned methods. Table 4 shows the evaluation results.

### Examples 2-2 and 2-3

A dispersion liquid of polishing silica fine particles was obtained in the same manner as in Example 2-1, except that the preparation conditions were changed as shown in Table 3.

The dispersion liquid of polishing silica fine particles obtained was evaluated similarly to Example 2-1. Table 4 shows the obtained results.

### Comparative 2-1

A dispersion liquid of polishing silica fine particles was obtained similarly to Comparative 1-1.

The dispersion liquid of polishing silica fine particles obtained was evaluated similarly to Example 2-1. Table 4 shows the obtained results.

### Comparative 2-2

Cataloid SI-45P (dispersion liquid of silica fine particles) manufactured by JGC Catalysts and Chemicals Ltd. was evaluated similarly to Example 2-1. Table 4 shows the obtained results.

TABLE 3

| | | | Ex. | Ex. | Ex. |
|---|---|---|---|---|---|
| | | Unit | 2-1 | 2-2 | 2-3 |
| Step | Pure water (amount added) | g | 304.66 | 315.9 | 440.12 |
| 1 | Acidic silicic acid solution (amount added) | g | 160.88 | 166.81 | 234.74 |
| | SiO₂ concentration | % by mass | 4.55 | 4.55 | 4.55 |
| | Aqueous solution of alkali hydroxide (amount added) | g | 6.72 | 6.97 | 9.81 |
| | Concentration of alkali hydroxide | mass% | 48.7 | 48.7 | 48.7 |
| | Type of alkali hydroxide | — | Potassium | Potassium | Potassium |
| | | | hydroxide | hydroxide | hydroxide |
| Step | Retention temperature | ° C. | 98 | 98 | 98 |
| 2 | Retention time | min | 30 | 30 | 30 |
| | Acidic silicic acid solution (amount added) | kg | 2.918 | 3.026 | 4.258 |
| | SiO₂ concentration | % by mass | 4.55 | 4.55 | 4.55 |
| | Time required for addition | hrs. | 11 | 11 | 11 |
| | Rate of addition | g/min | 4.42 | 4.58 | 6.45 |
| | Addition of pure water | g | 351.27 | 1,375.53 | |
| Step | Retention temperature | ° C. | 98 | 98 | 98 |
| 3 | Acidic silicic acid solution (total amount added) | kg | 14.338 | 11.493 | 20.925 |
| | SiO₂ concentration | % by mass | 4.55 | 4.55 | 4.55 |
| | Time required for addition | hrs. | 24 | 28 | 18 |
| | Rate of addition (from start until elapse of 4 hours) | g/min | 16.37 | 14.27 | 23.91 |
| | Rate of addition (from elapse of 4 hours until elapse of 8 hours) | g/min | 12.28 | 10.07 | 23.91 |
| | Rate of addition (from elapse of 8 hours until elapse of 12 hours) | g/min | 10.00 | 7.44 | 15.75 |
| | Rate of addition (from elapse of 12 hours until elapse of 16 hours) | g/min | 8.23 | 5.35 | 15.75 |
| | Rate of addition (from elapse of 16 hours until elapse of 18 hours) | g/min | 6.68 | 4.29 | 15.75 |
| | Rate of addition (from elapse of 18 hours until elapse of 20 hours) | g/min | 6.68 | 4.29 | |
| | Rate of addition (from elapse of 20 hours until elapse of 24 hours) | g/min | 6.19 | 3.50 | |
| | Rate of addition (from elapse of 24 hours until elapse of 28 hours) | g/min | | 2.97 | |
| | Rate at which silica dry in acidic silicic acid solution is added to silica dry | g/min-g | 0.0053 | 0.0048 | 0.0035 |
| | (at completion of first addition) | | | | |
| | Rate at which silica dry in acidic silicic acid solution is added to silica dry | g/min-g | 0.0040 | 0.0036 | 0.0018 |
| | (at completion of second addition) | | | | |
| | Rate at which silica dry in acidic silicic acid solution is added to silica dry | g/min-g | 0.0032 | 0.0028 | |
| | (at completion of third addition) | | | | |
| | Rate at which silica dry in acidic silicic acid solution is added to silica dry | g/min-g | 0.0026 | 0.0021 | |
| | (at completion of fourth addition) | | | | |
| | Rate at which silica dry in acidic silicic acid solution is added to silica dry | g/min-g | 0.0021 | 0.0017 | |
| | (at completion of fifth addition) | | | | |
| | Rate at which silica dry in acidic silicic acid solution is added to silica dry | g/min-g | 0.0019 | 0.0015 | |
| | (at completion of sixth addition) | | | | |
| | Rate at which silica dry in acidic silicic acid solution is added to silica dry | g/min-g | | 0.0013 | |
| | (at completion of seventh addition) | | | | |
| | Aqueous solution of alkali hydroxide (total amount added) | kg | 3.046 | 6.109 | 2.083 |
| | Concentration of alkali hydroxide | % by mass | 0.5 | 0.2 | 1.07 |
| | Time required for addition | hrs. | 24 | 28 | 18 |
| | Rate of addition (from start until elapse of 4 hours) | g/min | 3.48 | 7.64 | 2.37 |
| | Rate of addition (from elapse of 4 hours until elapse of 8 hours) | g/min | 2.61 | 5.36 | 2.37 |
| | Rate of addition (from elapse of 8 hours until elapse of 12 hours) | g/min | 2.12 | 3.96 | 1.57 |
| | Rate of addition (from elapse of 12 hours until elapse of 16 hours) | g/min | 1.75 | 2.84 | 1.57 |
| | Rate of addition (from elapse of 16 hours until elapse of 18 hours) | g/min | 1.43 | 2.25 | 1.57 |
| | Rate of addition (from elapse of 18 hours until elapse of 20 hours) | g/min | 1.43 | 2.25 | |
| | Rate of addition (from elapse of 20 hours until elapse of 24 hours) | g/min | 1.31 | 1.85 | |
| | Rate of addition (from elapse of 24 hours until elapse of 28 hours) | g/min | | 1.56 | |
| | Extracted solution (total amount extracted) | kg | 17.24 | 19.01 | 17.89 |
| | Time required for extraction | hrs. | 24 | 28 | 18 |
| | Rate of extraction (from start until elapse of 4 hours) | g/min | 19.78 | 23.73 | 20.32 |
| | Rate of extraction (from elapse of 4 hours until elapse of 8 hours) | g/min | 14.80 | 16.72 | 20.32 |
| | Rate of extraction (from elapse of 8 hours until elapse of 12 hours) | g/min | 12.02 | 12.31 | 13.56 |
| | Rate of extraction (from elapse of 12 hours until elapse of 16 hours) | g/min | 9.86 | 8.82 | 13.56 |
| | Rate of extraction (from elapse of 16 hours until elapse of 18 hours) | g/min | 8.00 | 7.04 | 13.56 |
| | Rate of extraction (from elapse of 18 hours until elapse of 20 hours) | g/min | 8.00 | 7.04 | |
| | Rate of extraction (from elapse of 20 hours until elapse of 24 hours) | g/min | 7.39 | 5.74 | |
| | Rate of extraction (from elapse of 24 hours until elapse of 28 hours) | g/min | | 4.84 | |
| | Silica dry in acidic silicic acid solution (X)/Silica dry in extracted solution (Z) | — | — | — | — |
| | X/Z value (from start until elapse of 4 hours) | — | 1.00 | 0.92 | 1.29 |
| | X/Z value (from elapse of 4 hours until elapse of 8 hours) | — | 1.01 | 0.92 | 1.29 |
| | X/Z value (from elapse of 8 hours until elapse of 12 hours) | — | 1.01 | 0.93 | 1.28 |
| | X/Z value (from elapse of 12 hours until elapse of 16 hours) | — | 1.01 | 0.93 | 1.28 |
| | X/Z value (from elapse of 16 hours until elapse of 18 hours) | — | 1.01 | 0.93 | 1.28 |
| | X/Z value (from elapse of 18 hours until elapse of 20 hours) | — | 1.01 | 0.93 | |
| | X/Z value (from elapse of 20 hours until elapse of 24 hours) | — | 1.02 | 0.93 | |
| | X/Z value (from elapse of 24 hours until elapse of 28 hours) | — | | 0.94 | |
| Step | Reaction solution remaining in reaction vessel at completion of step 3 | kg | 3.50 | 3.22 | 9.97 |
| 4 | (residual amount) | | | | |
| | Aging temperature | ° C. | 98 | 98 | 98 |
| | Aging time | hrs. | 1 | 1 | 1 |
| | pH after completion of step 4 | — | 10.1 | 10.0 | 10.2 |

In Table 3, “Rate at which silica dry in acidic silicic acid solution is added to silica dry (at completion of first addition)” refers to the mass [g] of silica dry in the acid silicic acid solution added per minute per mass [g] of silica particles (silica dry) contained in the solution in the reaction vessel filled with the Step 3b solution in Process A of Step 3b.

Here, “at completion of first addition” refers to at the completion of the first addition when the rate of addition of the acidic silicic acid solution is changed multiple times. In Example 2-1, the first addition is completed at the elapse of 4 hours, the second completed at the elapse of 8 hours, the third completed at the elapse of 12 hours, and so on.

TABLE 4

| | | Ex. | Ex. | Ex. | Comp. | Comp. |
|---|---|---|---|---|---|---|
| | Unit | 2-1 | 2-2 | 2-3 | 2-1 | 2-2 |
| Particle size in terms of specific surface area of group of particles | nm | 36.9 | 34.5 | 35.9 | 33.3 | 42.6 |
| Average sphericity of group of particles (image analysis) | — | 0.93 | 0.91 | 0.91 | 0.90 | 0.91 |
| Particle size distribution in terms of weight | nm | 26.5 | 26.4 | 33.0 | 33 | 52 |
| 10% cumulative particle size (D10) | | | | | | |
| Particle size distribution in terms of weight | nm | 54.8 | 49.7 | 63.2 | 48 | 58 |
| 50% cumulative particle size (D50) | | | | | | |
| Particle size distribution in terms of weight | nm | 105 | 99 | 82 | 79 | 70 |
| 90% cumulative particle size (D90) | | | | | | |
| Particle size distribution in terms of weight | — | 1.43 | 1.45 | 0.78 | 0.97 | 0.30 |
| (D90 − D10)/D50 | | | | | | |
| Particle size distribution in terms of weight | Yes or No | Yes | Yes | Yes | No | No |
| Distribution peak on large particle size side | | | | | | |
| Particle size distribution in terms of weight | nm | 86 | 89 | 69 | 27 | 37 |
| Peak position (particle size) on large particle size side | | | | | | |
| Irregularly-shaped particle proportion (image analysis) | % by number | 2.5 | 2.4 | 2.7 | 1.2 | 1.7 |
| Particle size distribution obtained from particle size/number of particles | % | 36.1 | 41.4 | 33.0 | 70.7 | 81.2 |
| CV value of particle size distribution area | | | | | | |
| PEI/SiO₂ dry ratio at equivalence point in streaming potential | — | 1.7 | 1.9 | 1.8 | 1.3 | 1.7 |
| measurement | | | | | | |
| Silica dry concentration in dispersion liquid of silica fine particles | % by mass | 12.0 | 12.0 | 12.0 | 12.0 | 40.5 |
| Polishing rate (SiO₂ film) | nm/min | 16 | 18 | 18 | 7 | 10 |
| Polishing rate (Aluminum hard disk) | nm/min | 80 | 54 | 80 | 64 | 38 |
| Scratches (Aluminum hard disk) | number | 2 | 8 | 6 | 46 | 13 |

### Examples 3-1 to 3-6

Examples 3-1 to 3-6 are described below. Table 5 shows the preparation conditions for Examples 3-1 to 3-6. Each dispersion liquid of polishing silica fine particles obtained was evaluated similarly to Example 1-1. Table 6 shows the obtained results.

### Example 3-1

Into a mixing vessel of a 10 L internal volume, 4,408 g of pure water was added, and 309.7 g of a dispersion liquid of silica fine particles (Cataloid SI-50 manufactured by JGC Catalysts and Chemicals Ltd., SiO₂ concentration: 48.43% by mass, Na₂O concentration: 0.48% by mass, particle size in terms of specific surface area: 25.5 nm) was further added. To this, 16.88 g of a solution obtained by diluting an aqueous potassium hydroxide solution (Super Kali R manufactured by TOAGOSEI CO., LTD., concentration: 48.7% by mass) with pure water to a concentration of 4.8% by mass was added, and stirred until homogenized. After stirring, the temperature was raised to 98 degrees C. and maintained for 30 minutes.

After that, 10.462 kg of an acidic silicic acid solution (SiO₂ concentration: 4.50% by mass) and 4.385 kg of an aqueous potassium hydroxide solution (concentration: 0.25% by mass) were added for 22 hours. Furthermore, in parallel with the addition, 14.66 kg of the solution mixture was extracted from the mixing vessel. The rate of addition of the acidic silicic acid solution, the rate of addition of the aqueous potassium hydroxide solution (concentration: 0.25% by mass), and the rate of extraction, at this time are shown in Table 5. After the addition and extraction are completed, 4.55 kg of the solution mixture remained in the mixing vessel, and this solution was kept at 98 degrees C. for 1 hour and then cooled to room temperature. The ratio of silica dry in the acidic silicic acid solution to silica dry in the extracted solution (silica dry in acidic silicic acid solution/silica dry in extracted solution) during mixing is shown in Table 5.

The solution mixture remaining in the mixing vessel and the extracted solution mixture were mixed until homogenized. The resulting mixture had a pH of 10.2, a particle size in terms of specific surface area of 44.0 nm, and a SiO₂ concentration of 3.17% by mass. This mixture was concentrated using an ultrafiltration membrane SIP-1013 manufactured by Asahi Kasei Corporation until the SiO₂ concentration reached 12.0% by mass.

### Example 3-2

Into a mixing vessel of a 10 L internal volume, 4,381 g of pure water was added, and 309.7 g of a dispersion liquid of silica fine particles (Cataloid SI-50 manufactured by JGC Catalysts and Chemicals Ltd., SiO₂ concentration: 48.43% by mass, Na₂O concentration: 0.48% by mass, particle size in terms of specific surface area: 25.5 nm) was further added. To this, 41.20 g of a solution obtained by diluting an aqueous potassium hydroxide solution (Super Kali R manufactured by TOAGOSEI CO., LTD., concentration: 48.7% by mass) with pure water to a concentration of 4.8% by mass was added, and stirred until homogenized. After stirring, the temperature was raised to 98 degrees C. and maintained for 30 minutes.

After that, 10.462 kg of an acidic silicic acid solution (SiO₂ concentration: 4.50% by mass) and 4.315 kg of an aqueous potassium hydroxide solution (concentration: 0.33% by mass) were added for 22 hours. Furthermore, in parallel with the addition, 14.48 kg of the solution mixture was extracted from the mixing vessel. The rate of addition of the acidic silicic acid solution, the rate of addition of the aqueous potassium hydroxide solution (concentration: 0.33% by mass), and the rate of extraction, on this occasion are shown in Table 5. After the addition and extraction are completed, 4.68 kg of the solution mixture remained in the mixing vessel, and this solution was kept at 98 degrees C. for 1 hour and then cooled to room temperature. The ratio of silica dry in the acidic silicic acid solution to silica dry in the extracted solution (silica dry in acidic silicic acid solution/silica dry in extracted solution) during mixing is shown in Table 5.

The solution mixture remaining in the mixing vessel and the extracted solution mixture were mixed until homogenized. The resulting mixture had a pH of 10.3, a particle size in terms of specific surface area of 47.8 nm, and a SiO₂ concentration of 3.17% by mass. This mixture was concentrated using an ultrafiltration membrane SIP-1013 manufactured by Asahi Kasei Corporation until the SiO₂ concentration reached 12.0% by mass.

### Example 3-3

Into a mixing vessel of a 10 L internal volume, 4,371 g of pure water was added, and 309.7 g of a dispersion liquid of silica fine particles (Cataloid SI-50 manufactured by JGC Catalysts and Chemicals Ltd., SiO₂ concentration: 48.43% by mass, Na₂O concentration: 0.48% by mass, particle size in terms of specific surface area: 25.5 nm) was further added. To this, 16.88 g of a solution obtained by diluting an aqueous potassium hydroxide solution (Super Kali R manufactured by TOAGOSEI CO., LTD., concentration: 48.7% by mass) with pure water to a concentration of 4.8% by mass was added, and stirred until homogenized. After stirring, the temperature was raised to 98 degrees C. and maintained for 30 minutes.

After that, 10.347 kg of an acidic silicic acid solution (SiO₂ concentration: 4.50% by mass) and 4.391 kg of an aqueous potassium hydroxide solution (concentration: 0.25% by mass) were added for 29 hours. Furthermore, in parallel with the addition, 14.52 kg of the solution mixture was extracted from the mixing vessel. The rate of addition of the acidic silicic acid solution, the rate of addition of the aqueous potassium hydroxide solution (concentration: 0.25% by mass), and the rate of extraction, on this occasion are shown in Table 5. After the addition and extraction are completed, 4.54 kg of the solution mixture remained in the mixing vessel, and this solution was kept at 98 degrees C. for 1 hour and then cooled to room temperature. The ratio of silica dry in the acidic silicic acid solution to silica dry in the extracted solution (silica dry in acidic silicic acid solution/silica dry in extracted solution) during mixing is shown in Table 5.

The solution mixture remaining in the mixing vessel and the extracted solution mixture were mixed until homogenized. The resulting mixture had a pH of 10.1, a particle size in terms of specific surface area of 45.5 nm, and a SiO₂ concentration of 3.19% by mass. This mixture was concentrated using an ultrafiltration membrane SIP-1013 manufactured by Asahi Kasei Corporation until the SiO₂ concentration reached 12.0% by mass.

### Example 3-4

Into a mixing vessel of a 10 L internal volume, 4,381 g of pure water was added, and 309.7 g of a dispersion liquid of silica fine particles (Cataloid SI-50 manufactured by JGC Catalysts and Chemicals Ltd., SiO₂ concentration: 48.43% by mass, Na₂O concentration: 0.48% by mass, particle size in terms of specific surface area: 25.5 nm) was further added. To this, 41.20 g of a solution obtained by diluting an aqueous potassium hydroxide solution (Super Kali R manufactured by TOAGOSEI CO., LTD., concentration: 48.7% by mass) with pure water to a concentration of 4.8% by mass was added, and stirred until homogenized. After stirring, the temperature was raised to 98 degrees C. and maintained for 30 minutes.

After that, 10.462 kg of an acidic silicic acid solution (SiO₂ concentration: 4.50% by mass) and 4.390 kg of an aqueous potassium hydroxide solution (concentration: 0.33% by mass) were added for 29 hours. Furthermore, in parallel with the addition, 14.81 kg of the solution mixture was extracted from the mixing vessel. The rate of addition of the acidic silicic acid solution, the rate of addition of the aqueous potassium hydroxide solution (concentration: 0.33% by mass), and the rate of extraction, on this occasion are shown in Table 5. After the addition and extraction are completed, 4.49 kg of the solution mixture remained in the mixing vessel, and this solution was kept at 98 degrees C. for 1 hour and then cooled to room temperature. The ratio of silica dry in the acidic silicic acid solution to silica dry in the extracted solution (silica dry in acidic silicic acid solution/silica dry in extracted solution) during mixing is shown in Table 5.

The solution mixture remaining in the mixing vessel and the extracted solution mixture were mixed until homogenized. The resulting mixture had a pH of 10.3, a particle size in terms of specific surface area of 47.0 nm, and a SiO₂ concentration of 3.17% by mass. This mixture was concentrated using an ultrafiltration membrane SIP-1013 manufactured by Asahi Kasei Corporation until the SiO₂ concentration reached 12.0% by mass.

### Example 3-5

Into a mixing vessel of a 200 L internal volume, 47.12 kg of pure water was added, and 4,350 g of a dispersion liquid of silica fine particles (Cataloid SI-50 manufactured by JGC Catalysts and Chemicals Ltd., SiO₂ concentration: 48.39% by mass, Na₂O concentration: 0.47% by mass, particle size in terms of specific surface area: 26.2 nm) was further added. To this, 219.22 g of a solution obtained by diluting an aqueous potassium hydroxide solution (Super Kali R manufactured by TOAGOSEI CO., LTD., concentration: 48.7% by mass) with pure water to a concentration of 4.8% by mass was added, and stirred until homogenized. After stirring, the temperature was raised to 95 degrees C. and maintained for 30 minutes.

After that, 147.75 kg of an acidic silicic acid solution (SiO₂ concentration: 4.50% by mass) and 15.5 kg of an aqueous potassium hydroxide solution (concentration: 1.0% by mass) were added for 18 hours. Furthermore, in parallel with the addition, 165.05 kg of the solution mixture was extracted from the mixing vessel. The rate of addition of the acidic silicic acid solution, the rate of addition of the aqueous potassium hydroxide solution (concentration: 1.0% by mass), and the rate of extraction, on this occasion are shown in Table 5. After the addition and extraction are completed, 48.95 kg of the solution mixture remained in the mixing vessel, and this solution was kept at 95 degrees C. for 1 hour and then cooled to room temperature. The ratio of silica dry in the acidic silicic acid solution to silica dry in the extracted solution (silica dry in acidic silicic acid solution/silica dry in extracted solution) during mixing is shown in Table 5.

The solution mixture remaining in the mixing vessel and the extracted solution mixture were mixed until homogenized. The resulting mixture had a pH of 10.3, a particle size in terms of specific surface area of 47.7 nm, and a SiO₂ concentration of 4.07% by mass. This mixture was concentrated using an ultrafiltration membrane SIP-2013 manufactured by Asahi Kasei Corporation until the SiO₂ concentration reached 12.0% by mass.

### Example 3-6

Into a mixing vessel of a 10 L internal volume, 3,494 g of pure water was added, and 289.3 g of a dispersion liquid of silica fine particles (Cataloid SI-50 manufactured by JGC Catalysts and Chemicals Ltd., SiO₂ concentration: 48.39% by mass, Na₂O concentration: 0.47% by mass, particle size in terms of specific surface area: 26.2 nm) was further added. To this, 16.81 g of a solution obtained by diluting an aqueous potassium hydroxide solution (Super Kali R manufactured by TOAGOSEI CO., LTD., concentration: 48.7% by mass) with pure water to a concentration of 4.8% by mass was added, and stirred until homogenized. After stirring, the temperature was raised to 98 degrees C. and maintained for 30 minutes.

After that, 15.193 kg of an acidic silicic acid solution (SiO₂ concentration: 4.50% by mass) and 3.157 kg of an aqueous potassium hydroxide solution (concentration: 0.5% by mass) were added for 22 hours. Furthermore, in parallel with the addition, 18.21 kg of the solution mixture was extracted from the mixing vessel. The rate of addition of the acidic silicic acid solution, the rate of addition of the aqueous potassium hydroxide solution (concentration: 0.5% by mass), and the rate of extraction, on this occasion are shown in Table 5. After the addition and extraction are completed, 3.66 kg of the solution mixture remained in the mixing vessel, and this solution was kept at 98 degrees C. for 1 hour and then cooled to room temperature. The ratio of silica dry in the acidic silicic acid solution to silica dry in the extracted solution (silica dry in acidic silicic acid solution/silica dry in extracted solution) during mixing is shown in Table 5.

The solution mixture remaining in the mixing vessel and the extracted solution mixture were mixed until homogenized. The resulting mixture had a pH of 10.1, a particle size in terms of specific surface area of 49.6 nm, and a SiO₂ concentration of 3.68% by mass. This mixture was concentrated using an ultrafiltration membrane SIP-1013 manufactured by Asahi Kasei Corporation until the SiO₂ concentration reached 12.0% by mass.

TABLE 5

| | | | | Ex. | Ex. | Ex. | Ex. | Ex. | Ex. |
|---|---|---|---|---|---|---|---|---|---|
| | | | Unit | 3-1 | 3-2 | 3-3 | 3-4 | 3-5 | 3-6 |
| Step | Pure water (amount added) | | g | 4,408 | 4,381 | 4,371 | 4,381 | 47,120 | 3,494 |
| 1 | Dispersion liquid of silica fine particles | | g | 309.7 | 309.7 | 309.7 | 309.7 | 4,350.0 | 289.3 |
| | (amount added) | | | | | | | | |
| | SiO₂ concentration | | % by mass | 48.43 | 48.43 | 48.43 | 48.43 | 48.39 | 48.35 |
| | Na₂O concentration | | % by mass | 0.48 | 0.48 | 0.48 | 0.48 | 0.47 | 0.49 |
| | Particle size in terms of specific surface area | | nm | 25.5 | 25.5 | 25.5 | 25.5 | 26.2 | 26.2 |
| | Aqueous solution of alkali hydroxide (amount added) | | g | 16.88 | 41.20 | 16.88 | 41.20 | 219.22 | 16.81 |
| | Concentration of alkali hydroxide | | % by mass | 4.8 | 4.8 | 4.8 | 4.8 | 4.8 | 4.8 |
| Step | Retention temperature | | ° C. | 98 | 98 | 98 | 98 | 95 | 98 |
| 2 | Retention time | | min | 30 | 30 | 30 | 30 | 30 | 30 |
| | Acidic silicic acid solution (total amount added) | | kg | 10.462 | 10.462 | 10.347 | 10.462 | 147.750 | 15.193 |
| | SiO₂ concentration | | % by mass | 4.50 | 4.50 | 4.55 | 4.50 | 4.50 | 4.45 |
| | Time for addition | First addition | hrs. | 0 to 6 | 0 to 6 | 0 to 5 | 0 to 5 | 0 to 9 | 0 to 9 |
| | | Second addition | hrs. | 6 to 11 | 6 to 11 | 5 to 11 | 5 to 11 | 9 to 18 | 9 to 22 |
| | | Third addition | hrs. | 11 to 22 | 11 to 22 | 11 to 29 | 11 to 29 | | |
| | Rate of addition | First addition | g/min | 11.13 | 11.1 | 13.16 | 13.44 | 155.39 | 20.23 |
| | | Second addition | g/min | 8.46 | 8.45 | 6.96 | 7.11 | 118.22 | 5.47 |
| | | Third addition | g/min | 5.94 | 5.96 | 3.6 | 3.58 | | |
| | Aqueous solution of alkali hydroxide (total amount | | kg | 4.385 | 4.315 | 4.391 | 4.390 | 15.500 | 3.157 |
| | added) | | | | | | | | |
| | Concentration of alkali hydroxide | | % by mass | 0.25 | 0.33 | 0.25 | 0.33 | 1.00 | 0.50 |
| | Rate of addition | First addition | g/min | 4.69 | 4.62 | 5.63 | 5.6 | 16.43 | 4.19 |
| | | Second addition | g/min | 3.56 | 3.49 | 2.96 | 2.94 | 12.27 | 1.15 |
| | | Third addition | g/min | 2.47 | 2.43 | 1.52 | 1.53 | | |
| | Extracted solution (total amount extracted) | | kg | 14.66 | 14.48 | 14.52 | 14.81 | 165.05 | 18.21 |
| | Rate of extraction | First addition | g/min | 15.63 | 15.44 | 18.55 | 18.93 | 174.99 | 17.37 |
| | | Second addition | g/min | 11.84 | 11.7 | 9.77 | 9.97 | 130.66 | 11.31 |
| | | Third addition | g/min | 8.31 | 8.2 | 5.03 | 5.13 | | |
| | Reaction solution remaining in reaction vessel at | | kg | 4.55 | 4.68 | 4.54 | 4.49 | 48.95 | 3.66 |
| | completion of step 2 (residual amount) | | | | | | | | |
| | Silica dry in acidic silicic acid solution (X)/Silica | | — | — | — | — | — | — | — |
| | dry in extracted solution (Z) | | | | | | | | |
| | X/Z value | First addition | — | 1.01 | 1.02 | 1.01 | 1.01 | 0.98 | 1.41 |
| | | Second addition | — | 1.01 | 1.03 | 1.02 | 1.01 | 1.00 | 0.58 |
| | | Third addition | — | 1.01 | 1.03 | 1.02 | 0.99 | | |

| | | | | | | | |
|---|---|---|---|---|---|---|---|
| Aging temperature | ° C. | 98 | 98 | 98 | 98 | 95 | 98 |
| Aging time | Hrs. | 1 | 1 | 1 | 1 | 1 | 1 |

TABLE 6

| | | Ex. | Ex. | Ex. | Ex. | Ex. | Ex. |
|---|---|---|---|---|---|---|---|
| | Unit | 3-1 | 3-2 | 3-3 | 3-4 | 3-5 | 3-6 |
| Particle size in terms of specific surface area of group of particles | nm | 44.0 | 47.8 | 45.5 | 47.0 | 44.7 | 49.6 |
| Average sphericity of group of particles (image analysis) | — | 0.90 | 0.91 | 0.91 | 0.92 | 0.91 | 0.92 |
| Particle size distribution in terms of weight | nm | 36 | 39 | 37 | 37 | 36 | 42 |
| 10% cumulative particle size (D10) | | | | | | | |
| Particle size distribution in terms of weight | nm | 65 | 70 | 66 | 67 | 65 | 78 |
| 50% cumulative particle size (D50) | | | | | | | |
| Particle size distribution in terms of weight | nm | 101 | 102 | 102 | 102 | 99 | 105 |
| 90% cumulative particle size (D90) | | | | | | | |
| Particle size distribution in terms of weight | — | 1.00 | 0.90 | 0.99 | 0.97 | 0.98 | 0.80 |
| (D90 − D10)/D50 | | | | | | | |
| Particle size distribution in terms of weight | Yes or No | Yes | Yes | Yes | Yes | Yes | Yes |
| Distribution peak on large particle size side | | | | | | | |
| Particle size distribution in terms of weight | nm | 83 | 80 | 82 | 82 | 81 | 83 |
| Peak position (particle size) on large particle size side | | | | | | | |
| Irregularly-shaped particle proportion (image analysis) | % by number | 1.0 | 2.8 | 1.9 | 2.8 | 1.8 | 0.8 |
| Particle size distribution obtained from particle size/number of | % | 24.4 | 32.1 | 28.1 | 29.9 | 25.6 | 28.5 |
| particles | | | | | | | |
| CV value of particle size distribution area | | | | | | | |
| PEI/SiO₂ dry ratio at equivalence point in streaming potential | — | 1.6 | 1.5 | 1.3 | 1.8 | 1.1 | 1.5 |
| measurement | | | | | | | |
| Silica dry concentration in dispersion liquid of silica fine particles | % by number | 12.0 | 12.0 | 12.0 | 12.0 | 12.0 | 12.0 |
| Polishing rate (SiO₂ film) | nm/min | 12 | 12 | 13 | 17 | 12 | 13 |
| Polishing rate (Aluminum hard disk) | nm/min | 69 | 81 | 70 | 68 | 67 | 68 |
| Scratches (Aluminum hard disk) | number | 9 | 21 | 39 | 26 | 40 | 8 |

1. A dispersion liquid of polishing silica fine particles produced by dispersing, in a solvent, a group of particles containing silica fine particles and satisfying Requirements 1) to 4) below, a particle size in terms of specific surface area of the group of particles being in a range of 5 nm to 200 nm,
1) an average sphericity of the group of particles is in a range of 0.85 to 1.00;
2) in a particle size distribution in terms of weight of the group of particles, a 10% cumulative particle size (D₁₀), a 90% cumulative particle size (D₉₀), and a 50% cumulative particle size (D₅₀) cumulated from a smaller particle size side satisfy 0.5≤(D₉₀−D₁₀)/D₅₀≤3.0 (Numerical Formula F1);
3) the particle size distribution in terms of weight of the group of particles has a distribution peak on a large particle size side; and
4) the group of particles contains irregularly-shaped particles in a range of 0.01% by number to 10% by number.

2. The dispersion liquid of polishing silica fine particles according to claim 1, wherein the group of particles further satisfies Requirement 5) below,
5) in a particle size distribution obtained from a particle size/the number of particles of the group of particles, a particle size range from a 1% cumulative particle size (D₁) to a 99% cumulative particle size (D₉₉), cumulated from a smaller particle size side, is divided into six equal parts, and assuming that the divided six particle size ranges are designated as S1, S2, S3, S4, S5, and S6, respectively, a CV value of a particle size distribution area corresponding to each of the particle size ranges is in a range of 20.0% to 70.0%.

3. The dispersion liquid of polishing silica fine particles according to claim 1, wherein in streaming potential measurement on the dispersion liquid of polishing silica fine particles where cationic polymeric polyethyleneimine having a weight average molecular weight of 600 is used as a titration reagent, a mass ratio of polyethyleneimine to silica at an equivalence point is in a range of 1.0 to 1.9.

4. A method for producing a dispersion liquid of polishing silica fine particles, the method comprising Step 1a to Step 3a below:
Step 1a: introducing an alkali and a dispersion of seed particles into a reaction vessel that is kept unheated to obtain a solution mixture;
Step 2a: after Step 1a, uniformly stirring the solution mixture, then performing heating to a temperature range of 40 degrees C. to 98 degrees C. and maintaining the solution mixture in the temperature range of 40 degrees C. to 98 degrees C., followed by performing Process A and Process B below in parallel to prepare a reaction solution, and further subjecting the reaction solution to aging in a temperature range of 40 degrees to 98 degrees C. for 20 minutes or more and 120 minutes or less,
Process A: preparing the reaction solution by continuously or intermittently adding an acidic silicic acid solution and an alkali to the reaction vessel filled with the solution mixture, and
Process B: continuously or intermittently extracting some of the reaction solution from the reaction vessel;
Step 3a: mixing the reaction solution remaining in the reaction vessel at a completion of Step 2a with the reaction solution extracted in Process B of Step 2a to obtain the dispersion liquid of polishing silica fine particles.

5. The method for producing the dispersion liquid of polishing silica fine particles according to claim 4, wherein, when a rate of the addition [g/min] (in terms of silica dry) of the acidic silicic acid solution is represented by X, and a rate of the extraction [g/min] (in terms of silica dry) of the reaction solution is represented by Z, a value of a ratio (X/Z) of the rate of the addition of the acidic silicic acid solution to the rate of the extraction of the reaction solution is in a range of 0.2 to 3.0.

6. The method for producing the dispersion liquid of polishing silica fine particles according to claim 4, wherein, when the rate of the addition [g/min] of the acidic silicic acid solution in Step 2a is changed one or more times and an n-th addition rate is set to Lₙ [g/min], a relationship of Lₙ₊₁<Lₙ is satisfied.

7. A method for producing a dispersion liquid of polishing silica fine particles, the method comprising Step 1b to Step 4b below:
Step 1b: introducing an acidic silicic acid solution and an alkali into a reaction vessel that is kept unheated to obtain a first solution mixture;
Step 2b: after Step 1b, uniformly stirring the first solution mixture, then performing heating to a temperature range of 40 degrees C. to 98 degrees C. and maintaining the first solution mixture in the temperature range of 40 degrees C. to 98 degrees C., followed by continuously or intermittently adding the acidic silicic acid solution thereto while maintaining the temperature range of 40 degrees C. to 98 degrees C. to obtain a second solution mixture;
Step 3b: after Step 2b, performing Process A and Process B below in parallel,
Process A: continuously or intermittently adding an acidic silicic acid solution and an alkali to the reaction vessel filled with the second solution mixture to prepare a reaction solution, and
Process B: continuously or intermittently extracting some of the reaction solution from the reaction vessel of Process A;
Step 4b: subjecting the reaction solution obtained in Process A and Process B of Step 3b to aging in a temperature range of 40 degrees C. to 98 degrees C. for 20 minutes or more and 120 minute or less, and adding the reaction solution extracted in Process B of Step 3b thereto then mixing to obtain the dispersion liquid of polishing silica fine particles.

8. The method for producing the dispersion liquid of polishing silica fine particles according to claim 7, wherein, when a rate of the addition [g/min] (in terms of silica dry) of the acidic silicic acid solution in Step 3b is represented by X, and a rate of the extraction [g/min] (in terms of silica dry) of the reaction solution is represented by Z, a value of a ratio (X/Z) of the rate of the addition of the acidic silicic acid solution to the rate of the extraction of the reaction solution is in a range of 0.2 to 3.0.

9. The method for producing the dispersion liquid of polishing silica fine particles according to claim 7, wherein, when the rate of the addition [g/min] of the acidic silicic acid solution in Step 3b is changed one or more times and an n-th addition rate is set to Lₙ [g/min], a relationship of Lₙ₊₁<Lₙ is satisfied.
